(19) United States
(12) Patent Application Publication
(10) Pub. No.: US 2020/0354825 A1
(43) Pub. Date: Nov. 12, 2020

(54) BLACK MEMBER, METHOD FOR MANUFACTURING BLACK MEMBER, AND TIMEPIECE INCLUDING BLACK MEMBER

(71) Applicant: CITIZEN WATCH CO., LTD., Tokyo (JP)

(72) Inventor: Kotaro TAKAZAKI, Sayama-shi, Saitama (JP)

(73) Assignee: CITIZEN WATCH CO., LTD., Tokyo (JP)

(21) Appl. No.: 16/640,502

(22) PCT Filed: Jul. 3, 2018
(86) PCT No.: PCT/JP2018/025222

§ 371 Date: Feb. 20, 2020

(30) Foreign Application Priority Data
Aug. 21, 2017 (JP) 2017-158906

(51) Int. Cl. C23C 14/06; G04B 37/22; A44C 27/00; C23C 14/34; C22C 14/00

(52) U.S. Cl. CPC C23C 14/0641; G04B 37/22; G01J 3/46; C23C 14/3414; C22C 14/00; A44C 27/00

(57) ABSTRACT

A black member includes a base and a black layer laminated on the base. The black layer contains titanium aluminum nitride, titanium silicon nitride, or titanium aluminum silicon nitride. The black layer may also contain at least one type of elements selected from the group consisting of oxygen, fluorine, and carbon. When the black layer contains carbon, and assuming that a total amount of elements contained in the black layer is 100 at %, the black layer contains carbon of 10 at % or less. In a color evaluation according to an L*, a*, b* color system (CIE color system), the black layer satisfies L*≤48.0, −2.0≤a*≤3.0, and −3.5≤b*≤3.0.

### FIELD

The present invention relates to a black member, a method for manufacturing the black member, and a timepiece including the black member.

### BACKGROUND

Conventionally, black layers (black films) exterior components used for ornaments and decorative articles such as glasses, accessories, and timepieces, sporting goods, or the like are made of a titanium carbide (TiC) (main component is carbon (C)) film, a tungsten carbide (WC) (main component is C) film, or a diamond-like carbon (DLC) film. In case of the TiC film, a black TiC film is formed by forming an underlayer on a base, and by introducing a large amount of hydrocarbon gas (methane (CH₄) gas, acetylene (C₂H₂) gas, and the like) on the surface thereof. 80 at % to 90 at % of components of the TiC film obtained through this method is C, and the TiC film displays black color derived from C. Similar to the TiC film, 80 at % to 90 at % of components of the WC film is also C, and the WC film displays black color derived from C. It is to be noted that in the WC film, only the role of joining the carbon atoms is changed from titanium to tungsten, and there is little difference between the WC film and the TiC film in the characteristics or the like. The DLC film is made by a chemical vapor deposition (CVD) method, a sputtering method, or the like (Patent Literature 1). Moreover, depending on the film formation conditions, it is possible to adjust the composition of the DLC film from a carbon composition (SP2) to a diamond composition (SP3). The DLC film, which is the current mainstream, is formed between the carbon component (SP2) and the diamond component (SP3).

### CITATION LIST

### Patent Literature

Patent Literature 1: Japanese Patent Application Laid-open No. H4-80364

### SUMMARY

### Technical Problem

A large amount of hydrocarbon-based gas is used to form the TiC film, WC film, or DLC film. Consequently, the device is severely contaminated, and frequent maintenance is required. Moreover, the color tone of the film is not stable before and after maintenance takes place. The carbon composition in the DLC film is increased as the DLC film becomes close to black. As a result, the device will be contaminated more severely.

The present invention has been made in view of the above, and an object of the present invention is to provide a black member that displays black with a luxurious feel and that excels in productivity.

### Solution to Problem

A black member according to the invention includes a base; and a black layer laminated on the base, wherein the black layer contains titanium aluminum nitride, titanium silicon nitride, or titanium aluminum silicon nitride; the black layer optionally also contains at least one type of elements selected from the group consisting of oxygen, fluorine, and carbon, and when the black layer contains carbon, and assuming that a total amount of elements contained in the black layer is 100 at %, the black layer contains carbon of 10 at % or less; and in a color evaluation according to an L*, a*, b* color system (CIE color system), the black layer satisfies L*≤48.0, −2.0≤a*≤3.0, and −3.5≤b*≤3.0.

### Advantageous Effects of Invention

The black member of the present invention displays black with a luxurious feel and excels in productivity.

### BRIEF DESCRIPTION OF DRAWINGS

FIG. 1 is a sectional schematic diagram illustrating a structure of a black member 1 according to a first embodiment.

FIG. 2 is a sectional schematic diagram illustrating a structure of a black member 2 according to a second embodiment.

FIG. 3 is a sectional schematic diagram illustrating a structure of a black member 3 according to a third embodiment.

FIG. 4 is a sectional schematic diagram illustrating a structure of a black member 4 according to a fourth embodiment.

FIG. 5 is a sectional schematic diagram illustrating a structure of a black member 6 according to a sixth embodiment.

FIG. 6 is a sectional schematic diagram illustrating a structure of a black member 7 according to a seventh embodiment.

FIG. 7 is a graph illustrating refractive indexes of a black layer 12 (sample 1-1), a DLC film, a TiC film, and an ideal black layer.

FIG. 8 is a graph illustrating extinction coefficients of the black layer 12 (sample 1-1), the DLC film, the TiC film, and the ideal black layer.

FIG. 9 is a graph illustrating reflection rates of a black layer 12 (sample 1-1), the DLC film, the TiC film, and the ideal black layer.

FIG. 10 is a graph illustrating refractive indexes of a black layer 32 (sample 3-6), the ideal black layer, and the black layer 12 (Example 1, sample 1-1).

FIG. 11 is a graph illustrating extinction coefficients of the black layer 32 (sample 3-6), the ideal black layer, and the black layer 12 (Example 1, sample 1-1) FIG. 12 is a graph illustrating reflection rates of the black layer 32 (sample 3-6), the ideal black layer, and the black layer 12 (Example 1, sample 1-1).

FIG. 13 is a graph illustrating a change in hardness, by changing the amount of nitrogen gas and a Bias voltage to be applied to a base.

FIG. 14 is a graph illustrating a change in lightness (L*), by changing the amount of nitrogen gas and the Bias voltage to be applied to the base.

FIG. 15 is a graph illustrating a change in hardness of a nitride film by the Bias voltage, when a sintered body of Ti 60 wt % and Al 40 wt % was used.

FIG. 16 is a graph illustrating a change in hardness of a nitride film by the Bias voltage, when a sintered body of Ti 40 wt % and Al 60 wt % was used.

FIG. 17 is a graph illustrating a change in hardness of a nitride film by the Bias voltage, when a sintered body of Ti 30 wt % and Al 70 wt % was used.

FIG. 18 is a graph illustrating measurement results of crystallinity obtained using an XRD diffraction method.

FIG. 19 is a graph illustrating measurement results of crystallinity obtained using the XRD diffraction method.

FIG. 20 is a graph illustrating measurement results of crystallinity obtained using the XRD diffraction method.

### DESCRIPTION OF EMBODIMENTS

Hereinafter, modes (embodiments) for carrying out the present invention will be described in detail with reference to the accompanying drawings. It is not intended that the present invention be limited by what has been described in the following embodiments. Moreover, components described below include components that can be easily assumed by a person skilled in the art, and components that are substantially the same as those components. Furthermore, the components described below can be combined with one another as appropriate. Still furthermore, various omissions, substitutions, or changes may be made without departing from the spirit of the present invention.

Black Member

### First Embodiment

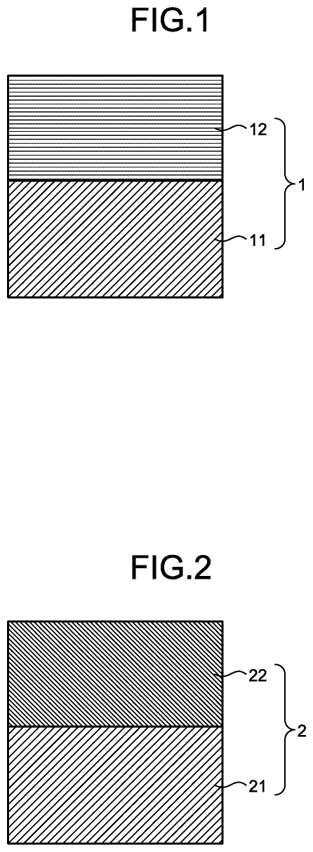

FIG. 1 is a sectional schematic diagram illustrating a structure of a black member 1 according to a first embodiment. The black member 1 in the first embodiment illustrated in FIG. 1 includes a base 11 and a black layer 12 laminated on the base 11.

The base 11 is a base made of metal, ceramics, or plastic. More specifically, the metal (including alloy) includes stainless steel, titanium, titanium alloy, copper, copper alloy, tungsten alloy; or hardened stainless steel, titanium, titanium alloy, and the like. These types of metal may be used alone, or two or more types may be combined. The shape of the base 11 is not limited.

The black layer 12 contains titanium aluminum nitride (TiAlN) (more specifically, titanium aluminum nitride crystal).

The black layer 12 contains titanium, aluminum, and nitrogen. Assuming that the total amount of elements contained in the black layer 12 is 100 at %, the black layer 12 contains titanium of 8.8 at % or more and 22.5 at % or less, and aluminum of 26.8 at % or more and 41.7 at % or less. Moreover, it is preferable that the black layer 12 contains nitrogen of 37.3 at % or more and 50.9 at % or less. When the amounts of elements described above fall within the range described above, the black layer 12 displays black with a luxurious feel. Moreover, the hardness of the black member 1 that includes the black layer 12 is increased. When the amount of titanium is increased within the range described above, the hardness of the black member 1 tends to increase. Furthermore, when the amount of nitrogen and titanium is reduced, the black layer 12 displays black with a more luxurious feel. The concentrations of titanium, aluminum, and nitrogen in the black layer 12 are preferably the same in the thickness direction (direction orthogonal to the base 11).

The black layer 12 may also contain oxygen and carbon as unavoidable elements. When the black layer 12 of the black member 1 according to the first embodiment contains carbon, and assuming that the total amount of elements contained in the black layer 12 is 100 at %, the black layer 12 may contain carbon in excess of 0 at % and 10 at % or less, and may preferably contain carbon in excess of 0 at % and 1 at % or less. Moreover, when the black layer 12 contains oxygen, and assuming that the total amount of elements contained in the black layer 12 is 100 at %, the black layer 12 may contain oxygen in excess of 0 at % and 6 at % or less.

It is preferable that the black layer 12 contains 90 at % or more of titanium, aluminum, and nitrogen in total. When the total amount of elements described above falls within the range described above, the black layer 12 displays black with a luxurious feel. Moreover, the hardness of the black member 1 that includes the black layer 12 is increased.

Whether the black layer 12 contains TiAlN can be confirmed by an X-ray diffraction method, Electron Spectroscopy for Chemical Analysis (ESCA), Energy Dispersive X-ray Spectroscopy (EDX), and the like. Moreover, for example, when the black layer 12 is formed using the following manufacturing method, it is considered that not only pure TiAlN is generated, but also TiAlN crystal containing oxygen or carbon is generated as TiAlN. This, too, can be confirmed by the X-ray diffraction method, ESCA, EDX, and the like. It is considered that titanium, aluminum, nitrogen, and unavoidable elements are also present as titanium nitride (TiN), aluminum nitride (AiN), titanium aluminum (TiAl), titanium carbide (TiC), aluminum carbon (AlC), oxide, and the like, in addition to TiAlN.

In view of preventing interference and obtaining black with a luxurious feel, the thickness of the black layer 12 is normally 0.55 μm or more, and preferably 0.6 μm or more. Moreover, in view of improving the scratch resistance and wear resistance of the black member 1, the thickness of the black layer 12 is preferably 4.0 μm or less.

A smooth film that does not absorb light due to the surface unevenness and the like, in other words, a metal-like film displays the most ideal black with a luxurious feel (piano black), when the refractive index (n) and the extinction coefficient (k), which are optical constants, are around 1 and 0.5, respectively. The black layer 12 (black layer 12 formed on the base 11) in the first embodiment has optical constants to represent black with a luxurious feel.

Moreover, in the color evaluation according to the L*, a*, b* color system (CIE color system), the black layer 12 (for example, the black layer 12 formed on an Si wafer as in Examples and the evaluation method of optical constants, which will be described below) satisfies normally L*≤48.0, −2.0≤a*≤3.0, and −3.5≤b*≤3.0. When L*, a*, and b* fall within the range described above, the black layer 12 displays black with a luxurious feel. a* represents color from red to green, and when a* is smaller than −2.0, it sometimes looks as though black is mixed with green, and when a* is greater than 3, it sometimes looks as though black is mixed with red. When b* is smaller than −3.5, it sometimes looks as though black is mixed with blue, and when b* is greater than 3.0, it sometimes looks as though black is mixed with yellow. Moreover, in the color evaluation according to the L*, a*, b* color system (CIE color system), the black member 1 (black member 1 that includes the black layer 12 formed on the base 11) satisfies normally L*≤48.0, −2.0≤a*≤3.0, and −3.5≤b*≤3.0.

Furthermore, the hardness of the black member 1 is normally Vickers Hardness (HV) 1000 or more. When the hardness of the black member 1 falls within the range described above, the black member 1 can also be suitably used in view of scratch resistance and wear resistance.

### Second Embodiment

FIG. 2 is a sectional schematic diagram illustrating a structure of a black member 2 according to a second embodiment. The black member 2 in the second embodiment illustrated in FIG. 2 includes a base 21 and a black layer 22 laminated on the base 21. The base 21 is the same as the base 11 in the first embodiment.

The black layer 22 contains titanium aluminum nitride (TiAlN) (more specifically, titanium aluminum nitride crystal). In this example, TiAlN not only includes pure TiAlN, but also includes titanium aluminum oxynitride (TiAlNO) that is TiAlN crystal containing oxygen.

The black layer 22 contains titanium, aluminum, nitrogen, and oxygen. Assuming that the total amount of elements contained in the black layer 22 is 100 at %, it is preferable that the black layer 22 contains titanium of 6.4 at % or more and 22.5 at % or less, aluminum of 21.4 at % or more and 38.1 at % or less, nitrogen of 20.2 at % or more and 42.3 at % or less, and oxygen of 12.9 at % or more and 34.9 at % or less. When the amounts of elements described above fall within the range described above, the black layer 22 displays black with a luxurious feel. Moreover, the hardness of the black member 2 that includes the black layer 22 is increased. It is preferable that the concentrations of titanium, aluminum, nitrogen, and oxygen contained in the black layer 22 are the same in the thickness direction (direction orthogonal to the base 21).

The black layer 22 may also contain carbon and the like as unavoidable elements. When the black layer 22 of the black member 2 according to the second embodiment contains carbon, and assuming that the total amount of elements contained in the black layer 22 is 100 at %, the black layer 22 may contain carbon in excess of 0 at % and 10 at % or less, and may preferably contain carbon in excess of 0 at % and 1 at % or less.

It is preferable that the black layer 22 contains 90 at % or more of titanium, aluminum, nitrogen, and oxygen in total. When the total amount of the elements described above falls within the range described above, the black layer 22 displays black with a luxurious feel. Moreover, the hardness of the black member 2 that includes the black layer 22 is increased.

Whether the black layer 22 contains TiAlN (more specifically, pure TiAlN, and TiAlNO that is TiAlN crystal containing oxygen) can be confirmed by the X-ray diffraction method, ESCA, EDX, and the like. Moreover, for example, when the black layer 22 is formed using the following manufacturing method, it is considered that TiAlN crystal containing carbon (may also be TiAlN that is TiAlN crystal containing oxygen and carbon) may also be generated as TiAlN. This, too, can be confirmed by the X-ray diffraction method, ESCA, EDX, and the like. It is assumed that titanium, aluminum, nitrogen, oxygen, and unavoidable elements are also present as TiN, AlN, TiAl, TiC, AlC, oxide, and the like, in addition to TiAlN.

In the second embodiment, the thickness, the optical constants (refractive index (n) and extinction coefficient (k)), and the range of L*, a*, and b* of the black layer 22; and the range of L*, a*, and b* and hardness of the black member 2 are the same as those in the first embodiment.

### Third Embodiment

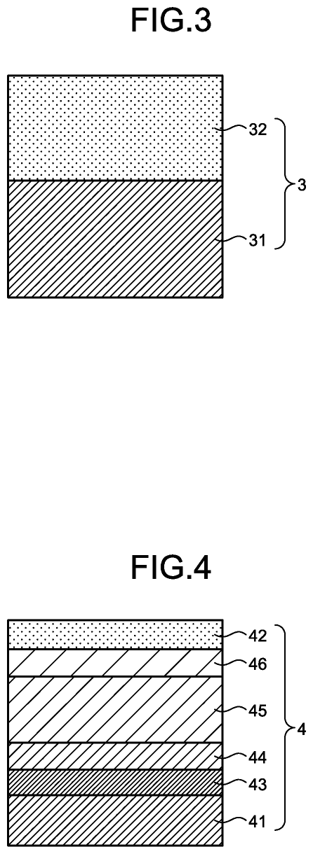

FIG. 3 is a sectional schematic diagram illustrating a structure of a black member 3 according to a third embodiment. The black member 3 in the third embodiment illustrated in FIG. 3 includes a base 31 and a black layer 32 laminated on the base 31. The base 31 is the same as the base 11 in the first embodiment.

The black layer 32 contains titanium aluminum nitride (TiAlN) (more specifically, titanium aluminum nitride crystal). In this example, TiAlN not only includes pure TiAlN, but also includes TiAlNF that is TiAlN crystal containing fluorine.

The black layer 32 contains titanium, aluminum, nitrogen, and fluorine. Assuming that the total amount of elements contained in the black layer 32 is 100 at %, the black layer 32 contains titanium of 6.4 at % or more and 22.5 at % or less, and aluminum of 21.4 at % or more and 38.1 at % or less. Moreover, it is preferable that the black layer 32 contains nitrogen of 20.2 at % or more and 42.3 at % or less, and fluorine of 14.2 at % or more and 29.2 at % or less. When the amounts of elements described above fall within the range described above, the black layer 32 displays black with a luxurious feel. It is preferable that the concentrations of titanium, aluminum, nitrogen, and fluorine in the black layer 32 are the same in the thickness direction (direction orthogonal to the base 31).

The black layer 32 may also contain oxygen, carbon, and the like as unavoidable elements. When the black layer 32 of the black member 3 according to the third embodiment contains carbon, and assuming that the total amount of elements contained in the black layer 32 is 100 at %, the black layer 32 may contain carbon in excess of 0 at % and 10 at % or less.

It is preferable that the black layer 32 contains 90 at % or more of titanium, aluminum, nitrogen, and fluorine in total. When the total amount of the elements described above falls within the range described above, the black layer 32 displays black with a luxurious feel.

Whether the black layer 32 contains TiAlN (more specifically, pure TiAlN, and TiAlNF that is TiAlN crystal containing fluorine) can be confirmed by the X-ray diffraction method, ESCA, EDX, and the like. Moreover, for example, when the black layer 32 is formed by the following manufacturing method, TiAlN that is TiAlN crystal containing oxygen or carbon (also TiAlN that is TiAlN crystal containing fluorine and oxygen or carbon) may also be present as TiAlN. This, too, can be confirmed by the X-ray diffraction method, ESCA, EDX, and the like. It is assumed that titanium, aluminum, nitrogen, fluorine, and unavoidable elements are also present as TiN, AlN, TiAl, TiC, AlC, fluoride, oxide, and the like, in addition to TiAlN.

In the third embodiment, the thickness, the optical constants (refractive index (n) and extinction coefficient (k)), and the range of L*, a*, and b* of the black layer 32; and the range of L*, a*, and b* of the black member 3 are the same as those in the first embodiment.

### Fourth and Fifth Embodiments

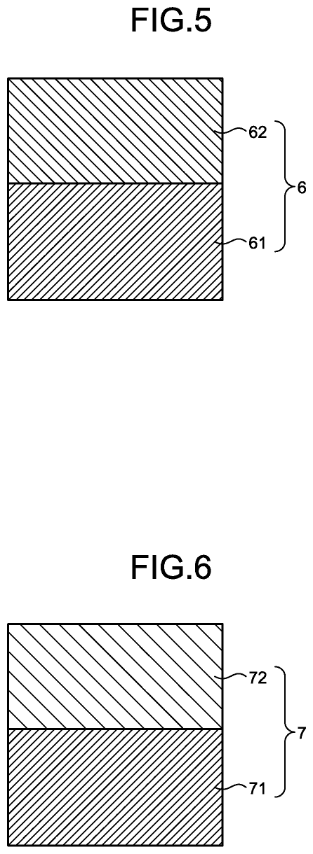

FIG. 4 is a sectional schematic diagram illustrating a structure of a black member 4 according to a fourth embodiment. The black member 4 in the fourth embodiment illustrated in FIG. 4 includes a base 41 and a black layer 42 laminated on the base 41. Moreover, the black member 4 in the fourth embodiment includes an adhesion layer 43, an adhesion gradient layer 44, a hardening layer 45, and a black gradient layer 46. The adhesion layer 43, the adhesion gradient layer 44, the hardening layer 45, and the black gradient layer 46 are laminated in this order between the base 41 and the black layer 42. The base 41 is the same as the base 11 in the first embodiment. The black layer 42 is the same as the black layer 32 in the third embodiment.

The adhesion layer 43 has low stress (in other words, low hardness). By providing the adhesion layer 43, it is possible to improve the adhesive force of the entire black member 4. The film hardness and the film stress are in a proportional relation, and the film stress is increased with an increase in the film hardness. For example, the film formed using the sputtering method has compression stress, and a peeling force from the base is applied to the film. When a film having high stress (hardness) is formed directly on the base 41 (SUS316L (about HV350) and the like) having low hardness, the film tends to peel off easily from the base 41 due to the difference in stress. Thus, it is preferable to form the adhesion layer 43 having low stress (hardness) on the base 41 first, without forming the film having high stress (hardness) directly on the base 41.

For example, the adhesion layer 43 is preferably formed of TiAl. Assuming that the total amount of elements contained in the adhesion layer 43 is 100 at %, it is preferable that the adhesion layer 43 contains titanium of 19.3 at % or more and 52.8 at % or less, and aluminum of 44.3 at % or more and 78.7 at % or less. The hardness of the adhesion layer 43 such as the above is normally HV800 or less. The thickness of the adhesion layer 43 is normally 0.03 μm or more and 0.3 μm or less.

The adhesion gradient layer 44 is a layer that joins the adhesion layer 43 and the hardening layer 45. The adhesion gradient layer 44 is formed such that the value of the film stress (film hardness) is increased in a gradient manner from the value at the adhesion layer 43 toward the value at the hardening layer 45, along the thickness direction (direction perpendicular to the base 41) from the adhesion layer 43 toward the hardening layer 45. By providing the adhesion gradient layer 44, similar to the adhesion layer 43, it is possible to relieve the sudden difference in stress between the films, and improve the adhesive force of the entire black member 4.

For example, the adhesion layer 43 side of the adhesion gradient layer 44 is made of TiAl having the same composition as that of the adhesion layer 43, and the hardening layer 45 side of the adhesion gradient layer 44 is made of TiAlN having the same composition as that of the hardening layer 45. It is preferable to form the adhesion gradient layer 44 such that the amount of nitrogen is increased, along the thickness direction (direction perpendicular to the base 41) from the adhesion layer 43 toward the hardening layer 45. The change in the amounts of elements can be confirmed by ESCA (Electron Spectroscopy for Chemical Analysis). The thickness of the adhesion gradient layer 44 is normally 0.03 μm or more and 1.0 μm or less.

The hardening layer 45 is formed so as to have a high hardness as possible. By providing the hardening layer 45, it is possible to improve the film hardness of the entire black member 4.

For example, the hardening layer 45 is preferably formed of TiAlN. Assuming that the total amount of elements contained in the hardening layer 45 is 100 at %, it is preferable that the hardening layer 45 contains titanium of 8.1 at % or more and 35.2 at % or less, aluminum of 30.4 at % or more and 41.3 at % or less, and nitrogen of 21.0 at % or more and 52.8 at % or less. The hardness of the hardening layer 45 such as the above is normally HV1000 or more. The thickness of the hardening layer 45 is normally 0.4 μm or more and 4.0 μm or less.

The black gradient layer 46 is a layer that joins the hardening layer 45 and the black layer 42. The black gradient layer 46 is formed such that the values of the refractive index and extinction coefficient approach the value at the black layer 42 from the value at the hardening layer 45 in a gradient manner, along the thickness direction (direction perpendicular to the base 41) from the hardening layer 45 toward the black layer 42. On an interface where the refractive index and the extinction coefficient differ greatly, interference of light tends to occur. When the black gradient layer 46 is not provided, interference of light tends to occur on the interface between the hardening layer 45 having a high lightness (for example, about L*70) and the black layer 42. The interference of light is a phenomenon of superposition of light that occurs between the light reflected from the surface of the black layer 42, and the light that has passed through the black layer 42, that is reflected by the interface between the black layer 42 and the hardening layer 45, and that has passed through the black layer 42 again. By providing the black gradient layer 46, it is possible to prevent the interference phenomenon from occurring, because the interface between the hardening layer 45 and the black layer 42 becomes unclear. As a result, it is possible to reduce the film thickness of the black layer 42.

For example, the hardening layer 45 side of the black gradient layer 46 is made of TiAlN having the same composition as that of the hardening layer 45. The black layer 42 side of the black gradient layer 46 has the same composition as that of the black layer 42. It is preferable to form the black gradient layer 46 such that the amount of nitrogen is changed and the amount of fluorine is increased, along the thickness direction (direction perpendicular to the base 41) from the hardening layer 45 toward the black layer 42. The change in the amounts of elements can be confirmed by ESCA (Electron Spectroscopy for Chemical Analysis). The thickness of the black gradient layer 46 is normally 0.03 μm or more and 0.06 μm or less.

Moreover, the black member 4 according to the fourth embodiment may also include a base and a black layer laminated on the base; and may further include an adhesion layer, a hardening layer, and a black gradient layer; and the adhesion layer, the hardening layer, and the black gradient layer may be laminated in this order between the base and the black layer. In other words, the black member 4 in the fourth embodiment may also have a structure (base/adhesion layer/hardening layer/black gradient layer/black layer) in which the adhesion gradient layer 44 is removed from the structure of the black member 4 in the fourth embodiment. In this case, the base is the same as the base 11 in the first embodiment, and the black layer is the same as the black layer 32 in the third embodiment. The adhesion layer, the hardening layer, and the black gradient layer are the same as the adhesion layer 43, the hardening layer 45, and the black gradient layer 46 in the fourth embodiment.

Furthermore, the black member 4 in the fourth embodiment may also include a base and a black layer laminated on the base; and further include at least one layer selected from the group consisting of the adhesion layer, the hardening layer, and the black gradient layer; and the adhesion layer, the hardening layer, and the black gradient layer may be laminated in this order between the base and the black layer. More specifically, the structure of the black member such as the above includes base/adhesion layer/black layer, base/hardening layer/black layer, base/black gradient layer/black layer, base/adhesion layer/hardening layer/black layer, base/adhesion layer/black gradient layer/black layer, and base/hardening layer/black gradient layer/black layer. In these cases, the base is the same as the base 11 in the first embodiment. The black layer is the same as the black layer 32 in the third embodiment. The adhesion layer, the hardening layer, and the black gradient layer are the same as the adhesion layer 43, the hardening layer 45, and the black gradient layer 46 in the fourth embodiment. The black gradient layer in this example corresponds to the black gradient layer 46 in which the hardening layer 45 is replaced with a layer under the black gradient layer (in other words, layer at the base side).

Moreover, a black member 5 in a fifth embodiment includes the black layer 12 in the first embodiment, instead of the black layer 42 in the fourth embodiment. Moreover, the black member 5 includes a black gradient layer, the hardening layer 45 side of which is made of TiAlN having the same composition as that of the hardening layer 45, and the black layer 12 side of which has the same composition as that of the black layer 12, instead of the black gradient layer 46. It is preferable to form the black member 5 such that the amount of nitrogen is changed, along the thickness direction (direction perpendicular to the base 41) from the hardening layer 45 toward the black layer 12.

Alternatively, the black member 5 in the fifth embodiment includes the black layer 22 in the second embodiment, instead of the black layer 42 in the fourth embodiment. Moreover, for example, the black member 5 includes a black gradient layer, the hardening layer 45 side of which is made of TiAlN having the same composition as that of the hardening layer 45, and the black layer 22 side of which has the same composition as that of the black layer 22, instead of the black gradient layer 46. It is preferable to form the black member 5 such that the amount of nitrogen is changed and the amount of oxygen is increased, along the thickness direction (direction perpendicular to the base 41) from the hardening layer 45 toward the black layer 22. The thickness of the black gradient layer in the fifth embodiment is the same as that of the black gradient layer 46.

Similar to the black member 4 in the fourth embodiment, the black member 5 in the fifth embodiment includes a base and a black layer laminated on the base; and further includes an adhesion layer, a hardening layer, and a black gradient layer; and the adhesion layer, the hardening layer, and the black gradient layer may be laminated in this order between the base and the black layer. Alternatively, the black member 5 may also include a base and a black layer laminated on the base; and further include at least one layer selected from the group consisting of an adhesion layer, a hardening layer, and a black gradient layer; and the adhesion layer, the hardening layer, and the black gradient layer may be laminated in this order between the base and the black layer. The specific structure of the black member 5 is the same as that of the black member 4 in the fourth embodiment.

Because the black member 4 in the fourth embodiment and the black member 5 in the fifth embodiment each have the specific black layer as described above, the black member 4 and the black member 5 display black with a luxurious feel. Moreover, because the black member 4 and the black member 5 each have a laminated structure, the black member 4 and the black member 5 have a high hardness and excel in scratch resistance and wear resistance. More specifically, it is normally L*≤48.0, −2.0≤a*≤3.0, −3.5≤b*≤3.0, and HV1000 or more.

### Sixth and Seventh Embodiments

FIG. 5 is a sectional schematic diagram illustrating a structure of a black member 6 according to a sixth embodiment. The black member 6 in the sixth embodiment illustrated in FIG. 5 includes a base 61 and a black layer 62 laminated on the base 61, and the black layer 62 contains titanium silicon nitride. In this example, the black layer 62 is described in the following (1) or (2).

(1) The black layer 62 contains titanium, silicon, and nitrogen. Assuming that the total amount of elements contained in the black layer 62 is 100 at %, the black layer 62 contains titanium of 5.9 at % or more and 16.2 at % or less, and silicon of 36.8 at % or more and 41.2 at % or less. Moreover, it is preferable that the black layer 62 contains nitrogen of 40.8 at % or more and 52.1 at % or less. The black layer 62 may also contain oxygen, carbon, and the like as unavoidable elements. When the black layer 62 of the black member 6 according to the sixth embodiment contains carbon, and assuming that the total amount of elements contained in the black layer 62 is 100 at %, the black layer 62 may contain carbon in excess of 0 at % and 10 at % or less, and may preferably contain carbon in excess of 0 at % and 1 at % or less. When the black layer 62 contains oxygen, and assuming that the total amount of elements contained in the black layer 12 is 100 at %, the black layer 62 may contain oxygen in excess of 0 at % and 6 at % or less.

(2) The black layer 62 contains titanium, silicon, nitrogen, and oxygen. Assuming that the total amount of elements contained in the black layer 62 is 100 at %, the black layer 62 contains titanium of 4.0 at % or more and 5.1 at % or less, and silicon of 32.2 at % or more and 37.2 at % or less. Moreover, it is preferable that the black layer 62 contains nitrogen of 42.1 at % or more and 48.2 at % or less, and oxygen of 14.1 at % or more and 16.5 at % or less. Furthermore, the black layer 62 may contain carbon and the like as unavoidable elements. When the black layer 62 of the black member 6 according to the sixth embodiment contains carbon, and assuming that the total amount of elements contained in the black layer 62 is 100 at %, the black layer 62 may contain carbon in excess of 0 at % and 10 at % or less, and may preferably contain carbon in excess of 0 at % and 1 at % or less.

The black member 6 in the sixth embodiment may also have the laminated structure described in the fourth and the fifth embodiments. The black member 6 of the sixth embodiment corresponds to the black member according to the first to the fifth embodiments in which aluminum is replaced with silicon.

FIG. 6 is a sectional schematic diagram illustrating a structure of a black member 7 according to a seventh embodiment. The black member 7 in the seventh embodiment illustrated in FIG. 6 includes a base 71 and a black layer 72 laminated on the base 71. The black layer 72 contains titanium aluminum silicon nitride. In this example, the black layer 72 is described in the following (3) or (4).

(3) The black layer 72 contains titanium, aluminum, silicon, and nitrogen. Assuming that the total amount of elements contained in the black layer 72 is 100 at %, the black layer 72 contains titanium of 16.8 at % or more and 20.5 at % or less, and aluminum and silicon of 30.2 at % or more and 33.6 at % or less in total. Moreover, it is preferable that the black layer 72 contains nitrogen of 45.5 at % or more and 52.5 at % or less. Furthermore, the black layer 72 may contain oxygen, carbon, and the like, as unavoidable elements. When the black layer 72 of the black member 7 according to the seventh embodiment contains carbon, and assuming that the total amount of elements contained in the black layer 72 is 100 at %, the black layer 72 may contain carbon in excess of 0 at % and 10 at % or less, and may preferably contain carbon in excess of 0 at % and 1 at % or less. Still furthermore, when the black layer 72 contains oxygen, and assuming that the total amount of elements contained in the black layer 12 is 100 at %, the black layer 72 may contain oxygen in excess of 0 at % and 6 at % or less.

(4) The black layer 72 contains titanium, aluminum, silicon, nitrogen, and oxygen. Moreover, the black layer 72 may also contain carbon and the like as unavoidable elements. When the black layer 72 of the black member 7 according to the seventh embodiment contains carbon, and assuming that the total amount of elements contained in the black layer 72 is 100 at %, the black layer 72 may contain carbon in excess of 0 at % and 10 at % or less, and may preferably contain carbon in excess of 0 at % and 1 at % or less.

The black member 7 in the seventh embodiment may also have the laminated structure described in the fourth and the fifth embodiments. The black member 7 in the seventh embodiment corresponds to the black member in the first to the fifth embodiments in which aluminum is replaced with aluminum and silicon.

Because the black member 6 in the sixth embodiment and the black member 7 in the seventh embodiment both have the specific black layer as described above, the black member 6 and the black member 7 display black with a luxurious feel. More specifically, it is normally L*≤48.0, −2.0≤a*≤3.0, and −3.5≤b*≤3.0.

The conventional black layer is made of TiC or DLC. Although the TiC layer displays black, the hardness thereof is low about HV300, and the TiC layer has low scratch resistance. Because the extinction coefficient of the TiC layer is small, the film thickness of the TiC layer needs to be 3 μm or more to display black color. Moreover, when the DLC layer has a carbon composition (SP2 hybrid orbitals), the hardness of the DLC layer is low, even though the DLC layer displays black. When the DLC layer has a diamond composition (SP3 hybrid orbitals), the hardness of the DLC layer is high at HV3000 and more, but because the refractive index is high and the extinction coefficient is substantially zero, the DLC layer produces rainbow-colored interference, even though the film thickness is increased. Consequently, although the DLC layer is formed between the carbon composition (SP2) and the diamond composition (SP3), the color tone of the DLC layer is close to gray at about HV1000. In any case, the main component of the TiC layer and the DLC layer, which are the conventional black layers, is carbon, and a large amount of hydrocarbon gas (CH₄ gas, C₂H₂ gas, toluene gas, and the like) is required during manufacturing. Thus, a large amount of coal adheres to the manufacturing device. When the coal is left unattended, insulation failure may occur in the manufacturing device. Moreover, the coal may contaminate the film by falling off from the manufacturing device and adhere to the film, while the film is being formed. Thus, for example, the maintenance cycle of the manufacturing device may be at least once a week, thereby lowering the productivity. Moreover, reproducibility of color tone is lowered before and after the maintenance.

On the contrary, because the black member of any embodiment has the specific black layer as described above, the black member displays black with a luxurious feel. Moreover, because the black layer hardly contains carbon, the maintenance cycle is long. For example, when the black member in the first embodiment is used, the maintenance cycle of the manufacturing device is about once in two months. Thus, the black member can considerably reduce the cost, and excels in productivity and reproducibility of color tone. In this manner, the black member of any embodiment can display black with a luxurious feel and has high productivity and reproducibility.

In the embodiments described above, the black member in the first embodiment and second embodiment, particularly, the black member in the second embodiment has a high hardness and excels in scratch resistance and wear resistance, due to the composition of the black layer. Moreover, the black member in the second embodiment and third embodiment, particularly, the black member in the third embodiment displays black with a luxurious feel, due to the composition of the black layer. Furthermore, the black member in the fourth embodiment and fifth embodiment, particularly, the black member in the fourth embodiment displays black with a more luxurious feel, and further excels in scratch resistance and wear resistance, due to the laminated structure. The scratch resistance is defined by a product of the substantial film thickness, the adhesion degree of the film, and the hardness of the film. When the layer described above is further provided between the base and the black layer, at least one of the film thickness, the adhesion degree of the film, and the hardness of the film will be improved. Thus, it is considered that the scratch resistance will be improved. Consequently, it is considered that the wear resistance will also be improved. Moreover, the black member in the embodiment that includes the black layer containing aluminum excels in the degree of blackness than that of the black member in the embodiment that includes the black layer containing silicon.

Furthermore, the black member according to the embodiments described above may also be a black member that includes a base and a black layer laminated on the base. The black layer described above contains titanium aluminum nitride, titanium silicon nitride, or titanium aluminum silicon nitride, and the black layer may also contain at least one type of elements selected from the group consisting of oxygen, fluorine, and carbon. When the black layer contains carbon, and assuming that the total amount of elements contained in the black layer described above is 100 at %, the black layer contains carbon of 10 at % or less. In the color evaluation according to the L*, a*, b* color system (CIE color system), the black layer is L*≤48.0, −2.0≤a*≤3.0, and −3.5≤b*≤3.0. In the black member described above, L*, a*, and b* of the black layer is required to be fall within the range described above. In other words, the amounts of titanium, aluminum, silicon, nitrogen, oxygen, and fluorine of the black member described above may not fall within the range described in the first to the seventh embodiments.

Method for Manufacturing Black Member

### Manufacturing Method of First Embodiment

A manufacturing method of the black member 1 in the first embodiment includes a process of laminating the black layer 12 on the base 11 (laminating process), by allowing alloy containing titanium and aluminum serving as the raw material alloy to react with nitrogen gas serving as the reactive gas, using a reactive sputtering method; and a process of obtaining the black member 1 by fabricating the base 11 laminated with the black layer 12 (fabricating process). With such a manufacturing method, it is possible to obtain the black member 1 in the first embodiment described above.

In the reactive sputtering method in the laminating process, high direct current or alternating current voltage is applied between the base 11 and a target composed of the constituent atoms of the black layer 12, while introducing inert gas (for example, argon (Ar) gas) into a chamber evacuated to vacuum. Next, the target constituent atoms are hit by causing the ionized Ar to collide with the target, and the black layer 12 is formed on the base 11 by using the substance. More specifically, by introducing a very small amount of reactive gas (for example, nitrogen gas) with Ar gas, a compound coating (black layer 12) of the target constituent atoms and nitrogen is formed on the base. In this example, to improve the adhesion, a Bias voltage may be applied to the base 11. The reactive sputtering method has high controllability of film quality and film thickness, and can be easily automated. Moreover, because the sputtered constituent atoms have high energy, there is no need to heat the base to improve the adhesion. Thus, it is also possible to form a film on a base such as plastic with a low melting point. Moreover, because the target constituent atoms being hit are formed on the base as a film, a high melting point material may also be used. Consequently, it is possible to expand the range of selection of material.

More specifically, it is preferable to use a sintered body or a molten metal alloy for alloy containing titanium and aluminum, which is the raw material alloy. Moreover, it is preferable that the raw material alloy contains aluminum of 43 at % or more and 81 at % or less. It is preferable that the remaining of the raw material alloy is titanium. By using the raw material alloy having the composition described above, it is possible to obtain the black layer 12 described above.

The inert gas includes Ar gas, krypton (Kr) gas, and xenon (Xe) gas, and Ar gas is preferably used.

For example, the composition of the black layer 12 can be adjusted by the composition of the raw material alloy, and the type and amount of reactive gas and inert gas. In other words, it is possible to adjust the adhesion, hardness, optical constants, and color tone of the black layer 12. It is also possible to adjust the hardness, optical constants, and color tone of the black layer 12, by the voltage or Bias voltage to be applied between the base 11 and the target. In this manner, by changing the film formation conditions such as the composition of the raw material alloy, the type and amount of the gas described above, and voltage, it is possible to adjust the color tone from reddish black to bluish black. Consequently, it is preferable to suitably select the conditions to display pure black with a little trace of color as much as possible. More specific film formation conditions will be described in the following Examples. Moreover, the thickness of the black layer 12 can also be adjusted by the sputtering time.

The fabrication process can be suitably performed by a known method.

### Manufacturing Method of Second Embodiment

A manufacturing method of the black member 2 in the second embodiment includes a process of laminating the black layer 22 on the base 21, by allowing alloy containing titanium and aluminum serving as the raw material alloy to react with nitrogen gas and oxygen gas serving as the reactive gas, using the reactive sputtering method; and a process of obtaining the black member 2 by fabricating the base 21 laminated with the black layer 22. With such a manufacturing method, it is possible to obtain the black member 2 in the second embodiment described above.

The manufacturing method of the black member 2 in the second embodiment is the same as the manufacturing method of the black member 1 in the first embodiment, except that nitrogen gas and oxygen gas are used instead of nitrogen gas. In the manufacturing method of the black member 2 in the second embodiment, the adhesion, hardness, optical constants, and color tone of the black layer 22 can also be adjusted, by the quantity ratio of nitrogen gas and oxygen gas. More specific film formation conditions will be described in the following Examples.

### Manufacturing Method of Third Embodiment

A manufacturing method of the black member 3 in the third embodiment includes a process of laminating the black layer 32 on the base 31, by allowing alloy containing titanium and aluminum serving as the raw material alloy to react with nitrogen gas and fluorine-based gas serving as the reactive gas, using the reactive sputtering method; and a process of obtaining the black member 3 by fabricating the base 31 laminated with the black layer 32. With such a manufacturing method, it is possible to obtain the black member 3 in the third embodiment described above.

The manufacturing method of the black member 3 in the third embodiment is the same as the manufacturing method of the black member 1 in the first embodiment, except that nitrogen gas and fluorine-based gas are used instead of nitrogen gas. The fluorine-based gas includes tetrafluoromethane (CF₄) gas and sulfur hexafluoride (SF₆) gas, and CF₄ gas is suitably used. In manufacturing the black member 3 in the third embodiment, it is possible to prevent the contamination of the device, because reactive gas (gas containing C, such as CH₄ and C₂H₂) is used less than manufacturing the conventional black layer. Consequently, the productivity and reproducibility of the black member 3 in the third embodiment are high. In the manufacturing method of the black member 3 in the third embodiment, the adhesion, hardness, optical constants, and color tone of the black layer 32 can also be adjusted by the quantity ratio of nitrogen gas and fluorine-based gas. More specific film formation conditions will be described in the following Examples.

### Manufacturing Method of Fourth and Fifth Embodiments

The manufacturing method of the black member 4 in the fourth embodiment includes a process of laminating the adhesion layer 43 on the base 41, by using alloy containing titanium and aluminum serving as the raw material alloy; a process of laminating the adhesion gradient layer 44 on the adhesion layer 43, by allowing alloy containing titanium and aluminum serving as the raw material alloy to react with nitrogen gas serving as the reactive gas; a process of laminating the hardening layer 45 on the adhesion gradient layer 44, by allowing alloy containing titanium and aluminum serving as the raw material alloy to react with nitrogen gas serving as the reactive gas; a process of laminating the black gradient layer 46 on the hardening layer 45, by allowing alloy containing titanium and aluminum serving as the raw material alloy to react with nitrogen gas and fluorine-based gas serving as the reactive gas; and a process of laminating the black layer 42 on the black gradient layer 46, by allowing alloy containing titanium and aluminum serving as the raw material alloy to react with nitrogen gas and fluorine-based gas serving as the reactive gas, using the reactive sputtering method; and a process of obtaining the black member 4 by fabricating the base 41 laminated with the black layer 42. With such a manufacturing method, it is possible to obtain the black member 4 in the fourth embodiment described above.

In the process of laminating the adhesion layer 43, to obtain the adhesion layer 43 having the composition, hardness, and thickness as described above, it is preferable to suitably select the composition of the raw material alloy, the type and amount of reactive gas and inert gas, the sputtering time, voltage, and the like.

In the process of laminating the adhesion gradient layer 44, to obtain the adhesion gradient layer 44 having the composition and thickness as described above, it is preferable to suitably select the composition of the raw material alloy, the type and amount of reactive gas and inert gas, the sputtering time, voltage, and the like. More specifically, it is preferable to laminate the adhesion gradient layer 44 while increasing the amount of nitrogen gas.

In the process of laminating the hardening layer 45, to obtain the hardening layer 45 having the composition, hardness, and thickness as described above, it is preferable to suitably select the composition of the raw material alloy, the type and amount of reactive gas and inert gas, the sputtering time, voltage, and the like.

In the process of laminating the black gradient layer 46, to obtain the black gradient layer 46 having the composition and thickness as described above, it is preferable to suitably select the composition of the raw material alloy, the type and amount of reactive gas and inert gas, the sputtering time, voltage, and the like. More specifically, it is preferable to laminate the black gradient layer 46, while changing the amount of nitrogen gas, and increasing the amount of fluorine-based gas.

The process of laminating the black layer 42 is the same as that in the manufacturing method of the third embodiment.

Moreover, when the black member 4 according to the fourth embodiment includes a base and a black layer laminated on the base; further includes an adhesion layer, a hardening layer, and a black gradient layer; and the adhesion layer, the hardening layer, and the black gradient layer are laminated in this order between the base and the black layer (when it is base/adhesion layer/hardening layer/black gradient layer/black layer); or when the black member 4 includes a base and a black layer laminated on the base; further includes at least one layer selected from the group consisting of an adhesion layer, a hardening layer, and a black gradient layer; and the adhesion layer, the hardening layer, and the black gradient layer are laminated in this order between the base and the black layer, the black member 4 can be manufactured by suitably combining the processes described above.

Moreover, instead of including the process of laminating the black gradient layer 46 and the process of laminating the black layer 42 in the manufacturing method of the fourth embodiment, the manufacturing method of the black member 1 in the fifth embodiment includes a process of laminating a black gradient layer on the hardening layer 45, by allowing alloy containing titanium and aluminum serving as the raw material alloy to react with nitrogen gas serving as the reactive gas, and a process of laminating the black layer 12 in the first embodiment on the black gradient layer, by allowing alloy containing titanium and aluminum serving as the raw material alloy to react with nitrogen gas serving as the reactive gas. In the process of laminating the black gradient layer, to obtain the black gradient layer having the composition and thickness as described above, it is preferable to suitably select the composition of the raw material alloy, the type and amount of reactive gas and inert gas, the sputtering time, voltage, and the like. More specifically, it is preferable to laminate the black gradient layer while changing the amount of nitrogen gas. The process of laminating the black layer 12 is the same as that in the manufacturing method of the first embodiment.

Alternatively, instead of including the process of laminating the black gradient layer 46 and the process of laminating the black layer 42 in the manufacturing method of the fourth embodiment, the manufacturing method of the black member 1 in the fifth embodiment includes a process of laminating a black gradient layer on the hardening layer 45, by allowing alloy containing titanium and aluminum serving as the raw material to react with nitrogen gas and oxygen gas serving as the reactive gas; and a process of laminating the black layer 22 in the second embodiment on the black gradient layer, by allowing alloy containing titanium and aluminum serving as the raw material alloy to react with nitrogen gas and oxygen gas serving as the reactive gas. In the process of laminating the black gradient layer, to obtain the black gradient layer having the composition and thickness described above, it is preferable to suitably select the composition of the raw material alloy, the type and amount of reactive gas and inert gas, the sputtering time, voltage, and the like. More specifically, it is preferable to laminate the black gradient layer while changing the amount of nitrogen gas and increasing oxygen gas. The process of laminating the black layer 22 is the same as that in the manufacturing method of the second embodiment.

With such a manufacturing method, it is possible to obtain the black member 5 in the fifth embodiment as described above.

When the black member 5 according to the fifth embodiment includes a base and a black layer laminated on the base; further includes an adhesion layer, a hardening layer, and a black gradient layer; and when the adhesion layer, the hardening layer, and the black gradient layer are laminated in this order between the base and the black layer (when it is base/adhesion layer/hardening layer/black gradient layer/black layer), or when the black member 5 includes a base and a black layer laminated on the base; further includes at least one layer selected from the group consisting of an adhesion layer, a hardening layer, and a black gradient layer; and the adhesion layer, the hardening layer, and the black gradient layer are laminated in this order between the base and the black layer, the black member 5 can be manufactured by suitably combining the processes described above.

### Manufacturing Method of Sixth and Seventh Embodiments

The manufacturing method of the black member 6 in the sixth embodiment corresponds to the manufacturing method of the first to the fifth embodiments in which aluminum is replaced with silicon. Moreover, the manufacturing method of the black member 7 in the seventh embodiment corresponds to the manufacturing method of the first to the fifth embodiments in which aluminum is replaced with aluminum and silicon (for example, alloy containing titanium, aluminum, and silicon is used, instead of alloy containing titanium and aluminum serving as the raw material alloy). With such a manufacturing method, it is possible to obtain the black member 6 in the sixth embodiment and the black member 7 in the seventh embodiment as described above.

The manufacturing method of the black member of the embodiments may also be performed by an arc method, an ion plating method, and the like, in addition to the reactive sputtering method described above. In the arc method, the black member is formed by causing arc discharge in vacuum using a metal target as a cathode, and evaporating the target material and ionizing the metal by the generated electric energy. By applying a Bias voltage (negative voltage) to the base side, the metal ions are accelerated and adhere to the base surface with reactive gas particles. Thus, it is possible to form a dense film.

Moreover, the manufacturing method of the black member according to the embodiments described above may also be a manufacturing method of a black member that includes a base and a black layer laminated on the base; the black layer contains titanium aluminum nitride, titanium silicon nitride, or titanium aluminum silicon nitride; the black layer may also include at least one type of elements selected from the group consisting of oxygen, fluorine, and carbon; and when the black layer contains carbon, and assuming that the total amount of elements contained in the black layer is 100 at %, the black layer contains carbon of 10 at % or less; and in the color evaluation according to the L*, a*, b* color system (CIE color system), the black layer satisfies L*≤48.0, −2.0≤a*≤3.0, and −3.5≤b*≤3.0. More specifically, the manufacturing method of the black member may include a process of laminating the black layer on the base by allowing alloy containing titanium and aluminum, the alloy containing titanium and silicon, the alloy containing titanium and silicon, or the alloy containing titanium, aluminum, and silicon serving as the raw material alloy to react with nitrogen gas, nitrogen gas and oxygen gas, or nitrogen gas and fluorine-based gas serving as the reactive gas, by the reactive sputtering method or the arc method; and a process of obtaining the black member by fabricating the base laminated with the black layer. In other words, the amount of titanium, aluminum, silicon, nitrogen, oxygen, and fluorine of the obtained black member may not fall within the range described in the first to the seventh embodiments.

Ornament, Decorative Material, Sporting Equipment, and Tool

The ornament or a decorative article according to the embodiments is an ornament or a decorative article that has an exterior component, and a part or the whole of the exterior component described above is formed of the black member described above. The ornament or the decorative article includes timepieces, glasses, and accessories. More specifically, the timepiece according to the embodiments is a timepiece that has an exterior component, and a part or the whole of the exterior component is formed of the black member described above. The timepiece may be any one of a photovoltaic timepiece, a thermoelectric generating timepiece, a standard time radio wave reception type self-correction timepiece, a mechanical timepiece, and a general electronic timepiece. Conventional timepieces are easily scratched due to a rub with a shirt or by collision with a desk, a wall or the like. However, the timepiece according to the embodiments uses the black member described above. Thus, the timepiece not only displays black with a luxurious feel, but can also be inhibited from being scratched for many years, and can maintain a beautiful exterior. Such a timepiece is manufactured by a known method using the black member described above.

Moreover, the sporting goods according to the embodiments include sporting goods having an exterior component, and a part or the whole of the exterior component is formed of the black member described above. The sporting goods described above display black with a luxurious feel and excel in scratch resistance. Such sporting goods are manufactured by a known method using the black member described above.

Furthermore, a part or the whole of the tool according to the embodiments is formed of the black member described above. The tool described above excels in scratch resistance. Particularly, when the hardness of the black member is HV1000 or more, the tool is further preferable as a tool, because the tool excels in scratch resistance. Such a tool is manufactured by a known method using the black member described above.

Namely, the present invention relates to the followings.

(1) A black member including a base; and a black layer laminated on the base; in which the black layer contains titanium aluminum nitride, titanium silicon nitride, or titanium aluminum silicon nitride; the black layer may also contain at least one type of elements selected from the group consisting of oxygen, fluorine, and carbon, and when the black layer contains carbon, and assuming that a total amount of elements contained in the black layer is 100 at %, the black layer contains carbon of 10 at % or less; and in a color evaluation according to an L*, a*, b* color system (CIE color system), the black layer satisfies L*≤48.0, −2.0≤a*≤3.0, and −3.5≤b*≤3.0.

The black member according to (1) described above displays black with a luxurious feel and excels in productivity.

(2) The black member according to (1), in which hardness of the black member is HV1000 or more.

When the hardness falls within the range described above, the black member can be suitably used for ornaments, decorative articles, sporting goods, or tools.

(3) The black member according to (1) or (2), in which the black layer contains titanium aluminum nitride, and assuming that the total amount of elements contained in the black layer is 100 at %, the black layer contains titanium of 8.8 at % or more and 22.5 at % or less, and aluminum of 26.8 at % or more and 41.7 at % or less; and when the black layer contains oxygen, the black layer contains oxygen in excess of 0 at % and 6 at % or less.

The black member according to (2) described above displays black with a more luxurious feel, has a high hardness, and excels in scratch resistance and wear resistance.

(4) The black member according to any one of (1) to (3) further includes at least one layer selected from the group consisting of an adhesion layer, a hardening layer, and a black gradient layer; and the adhesion layer, the hardening layer, and the black gradient layer are laminated in this order between the base and the black layer.

(5) The black member according to (4) further includes the adhesion layer, the hardening layer, and the black gradient layer; and the adhesion layer, the hardening layer, and the black gradient layer are laminated in this order between the base and the black layer.

(6) The black member according to (5) further includes an adhesion gradient layer, and the adhesion gradient layer is laminated between the adhesion layer and the hardening layer.

The black member according to (4) to (6) described above displays black with a more luxurious feel, has a high hardness, and excels in scratch resistance and wear resistance.

(7) The black member according to any one of (1) to (6), in which the black layer described above has a thickness of 0.6 μm or more and 4.0 μm or less.

When the thickness of the black layer described above falls within the range described above, the black member displays black with a luxurious feel, has a high hardness, and excels in scratch resistance and wear resistance.

(8) A method for manufacturing a black member that includes a base and a black layer laminated on the base; in which the black layer contains titanium aluminum nitride, titanium silicon nitride, or titanium aluminum silicon nitride; the black layer may also contain at least one type of elements selected from the group consisting of oxygen, fluorine, and carbon, and when the black layer contains carbon, and assuming that a total amount of elements contained in the black layer is 100 at %, the black layer contains carbon of 10 at % or less; and in a color evaluation according to an L*, a*, b* color system (CIE color system), the black layer satisfies L*≤48.0, −2.0≤a*≤3.0, and −3.5≤b*≤3.0, the method for manufacturing the black member, includes: a process of laminating the black layer on the base, by allowing alloy containing titanium and aluminum, alloy containing titanium and silicon, or alloy containing titanium, aluminum, and silicon, serving as a raw material alloy to react with nitrogen gas, nitrogen gas and oxygen gas, or nitrogen gas and fluorine-based gas serving as the reactive gas, using a reactive sputtering method or an arc method; and a process of obtaining the black member by fabricating the base laminated with the black layer.

With the manufacturing method of the black member of [8] described above, it is possible to obtain the black member that displays black with a luxurious feel, and that excels in productivity.

[9] The method for manufacturing the black member according to (8), in which the raw material alloy described above contains aluminum of 43 at % or more and 81 at % or less.

When the raw material alloy described above is used, it is possible to obtain the black member that displays black with a luxurious feel, and that excels in productivity.

(10) A timepiece that includes an exterior component, in which a part or the whole of the exterior component described above is formed of the black member according to any one of (1) to (7).

The timepiece according to (10) described above displays black with a luxurious feel, inhibited from being scratched for many years, and can maintain a beautiful exterior.

Hereinafter, the present invention will be described more specifically on the basis of examples. However, the present invention is not limited to these examples.

### EXAMPLES

Evaluation Method

Optical Constants

A measurement method of optical constants was performed as follows. By measuring multiple waves (250 nm to 900 nm) of a black layer formed on an Si wafer base using an ellipsometer (manufactured by Horiba, UVISEL), the refractive index (n), the extinction coefficient (k), and the film thickness (d) were identified. The measurement method is a method generally used for measuring optical constants of a thin film. A reflectivity curve and color tone can be calculated by substituting the obtained optical constants at each wavelength in the following expressions (1) to (5).

$$\begin{matrix}COMPLEX REFRACTIVE INDEX {n}_{j} = n - ik & ( 1 ) \\ PHASE DIFFERENCE OF THIN FILM δ j = \frac{2 π {n}_{j} {d}_{j} cos θ}{λ} & ( 2 ) \\ [ \begin{matrix}{E}_{b} \\ {H}_{b}\end{matrix} ] = [ \begin{matrix}cos {δ}_{j} & i \frac{sin {δ}_{j}}{{n}_{j}} \\ {in}_{j} sin {δ}_{j} & cos {δ}_{j}\end{matrix} ] [ \begin{matrix}{E}_{a} \\ {H}_{a}\end{matrix} ] = [ \begin{matrix}cos {δ}_{j} {E}_{a} + i ( \frac{{H}_{a}}{{n}_{j}} ) sin {δ}_{j} \\ {in}_{j} sin {δ}_{j} + {H}_{a} cos {δ}_{j}\end{matrix} ] & ( 3 ) \\ OPTICAL ADMITTANCE Y = \frac{{H}_{b}}{{E}_{b}} & ( 4 ) \\ REFLECTION RATE R ( \% ) = ( \frac{{n}_{0} - Y}{{n}_{0} + Y} ) {( \frac{{n}_{0} - Y}{{n}_{0} + Y} )}^{*} & ( 5 )\end{matrix}$$

Film Thickness and Color Tone

In the film thickness measurement, specifically, a film was formed by introducing a masked Si wafer in a film formation device with a base. Next, after forming the film and removing the mask, a step between a masked portion and an unmasked portion was measured. The film thickness in the Examples is the film thickness obtained by forming a single layer film under the film formation conditions in advance, and controlling the film by time so as a predetermined film thickness can be obtained from the obtained film formation rate.

More specifically, the color tone measurement method (lightness and saturation) was carried out using Apectra Magic NX manufactured by KONICA MINOLTA. As for the color tone, L*, a*, and b* of each film according to the L*a*b* chromaticity diagram were measured by using a light source D65.

Film Hardness Measurement Method

The film hardness was measured by using a micro-indentation hardness tester (H100 manufactured by FISCHER). A Vickers indenter was used as a probe. Load of 5 mN was applied to the film for 10 seconds, and after removing the load, the film hardness was calculated from the depth of the inserted Vickers indenter.

Amounts of Elements

The amounts of elements that form the black layer were measured by ESCA (Electron Spectroscopy for Chemical Analysis). In ESCA, an element qualitatively determined on the surface of the black layer was sputter-etched from a top surface, and XPS photoelectron spectrum of each obtained element was detected and quantitatively determined.

Scratch Resistance Test

The scratch resistance test was performed as follows. First, a test sample was obtained by forming a black layer on an SUS316L base defined in Japan Industrial Standard (JIS). Next, a piece of abrasion paper in which alumina particles are uniformly dispersed was brought into contact with a test sample at a constant load, and scratches were generated on the test sample by rubbing the abrasion paper for a predetermined number of times. The surface roughness of the surface of the scratched test sample was measured, by scanning the surface in a direction perpendicular to the direction of the scratches. The scratch resistance was evaluated by the root-mean-square roughness. The scratch resistance can be numerically evaluated, because the value of the root-mean-square roughness is increased with an increase in the generation amount of scratches and an increase in the depth of scratches, and the value of the root-mean-square roughness is reduced with a reduction in the generation amount of scratches and with a reduction in the depth of scratches.

Evaluation

For the black member having the black layer obtained in the Examples, a double circle was given when L*, a*, and b* of the black member were within the range of L*≤48.0, −2.0≤a*≤3.0, and −3.5≤b*≤3.0, and the hardness was HV1000 or more. A single circle was given when L*, a*, and b* of the black member were within the range of L*≤48.0, −2.0≤a*≤3.0, and −3.5≤b*≤3.0, and the hardness was less than HV1000. A cross was given when L*, a*, and b* of the black member were not within the range of L*≤48.0, −2.0≤a*≤3.0, and −3.5≤b*≤3.0.

### Example 1

In Example 1, a sintered body of Ti 70 wt % and Al 30 wt % (Ti 57 at % and Al 43 at %) was used as a sputtering target (raw material alloy). As illustrated in FIG. 1, the SUS316L base defined in JIS was used as the base 11. The black member 1 was produced (sample 1-1) by forming the black layer 12 (TiAl alloy nitride film) with a thickness of 1.0 μm on the base 11, by introducing nitrogen gas of 35 sccm to the base 11, under a constant Ar gas amount of 105 sccm using the sputtering method. A Bias voltage for firmly attaching the film material to be sputtered was applied to the base 11, and Example 1 was performed under a fixed condition in which the Bias voltage is −10 V.

Moreover, by using the sintered body of Ti 70 wt % and Al 30 wt %, the black member 1 was produced (samples 1-2 to 1-10) by changing the amount of nitrogen gas. Table 1 indicates the film thickness, color tone, and film hardness of the black layer 12, and the film component measurement results by ESCA and the scratch resistance test results, of these samples. As a comparison, Table 1 also indicates the film thickness, color tone, film hardness, and the like of the DLC film, TiC film (company A and company B), and the ideal black layer, with the measurement results of TiAl. The refractive index of the ideal black layer (a smooth film that does not absorb light due to the surface unevenness and the like) is close to 1, and the extinction coefficient is around 0.5.

When the black member 1 was produced under the condition in which the nitrogen gas amount is 35 sccm or more, the color tone range (L*≤48.0, −2.0≤a*≤3.0, and −3.5≤b*≤3.0) that displays black with a luxurious feel is satisfied, and the film hardness of HV1000 or more that is effective for scratch resistance can be achieved.

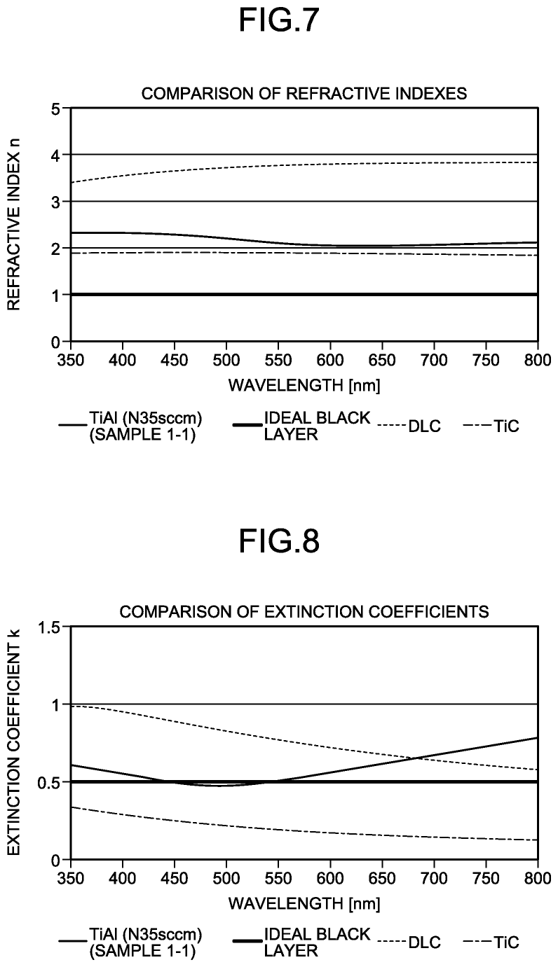

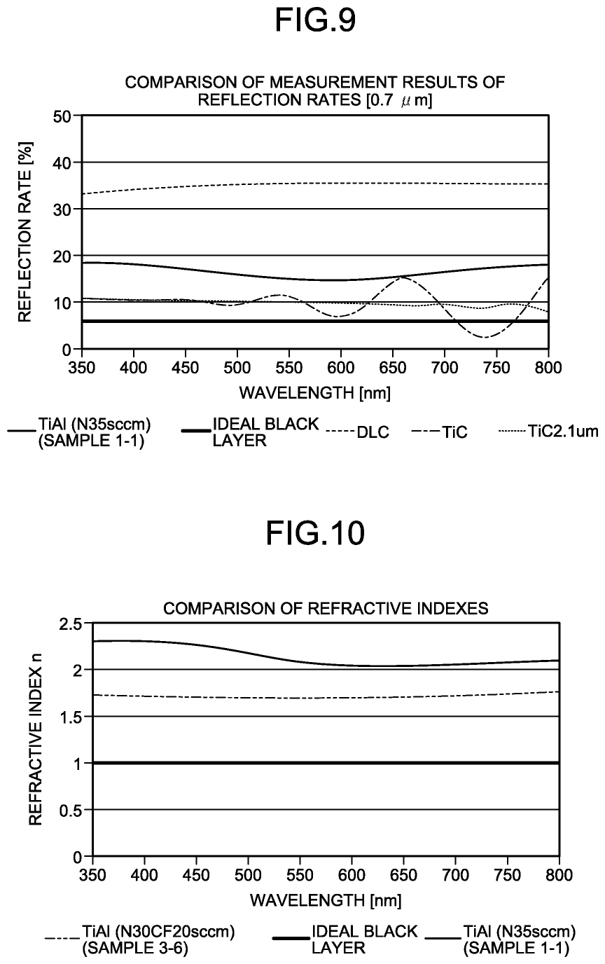

FIG. 7 to FIG. 9 are graphs each illustrating refractive indexes, extinction coefficients, and reflection rates simulated from the refractive index, extinction coefficient, and film thickness (0.7 μm) of the black layer 12 (sample 1-1), the DLC film, the TiC film, and an ideal black layer. FIG. 7 to FIG. 9 reveal that the reflection rate is reduced as the refractive index and the extinction coefficient approach an ideal material, and the color becomes blacker. From FIG. 9, when the film thickness of the TiC film is 0.7 μm, it is confirmed that the reflection rate is increased or reduced due to the thin film interference at the high-wavelength side. When the waveform has such a reflection rate the color around 650 nm and 800 nm is emphasized, and on the contrary, the color around 600 nm and 750 nm is reduced. Consequently, rainbow color-like interference occurs (multiple interference of the reflected light), and black color will not be displayed. This is because the extinction coefficient of the TiC film is lower than that of the ideal black layer (FIG. 8), and the light that has entered the film is not sufficiently absorbed in the film and returns from the base side as reflected light. In other words, this is a phenomenon caused when the reflected light from the surface of the black member and the reflected light that has returned from the base side interfere with each other. To make the TiC film black, the reflected light from the base needs to be eliminated by sufficiently increasing the film thickness, and the minimum film thickness needs to be about 2.1 μm. Moreover, from the refractivity simulation, the black layer 12 that has used the sintered body of Ti 70 wt % and Al 30 wt % becomes a black layer without interference at the film thickness of 0.55 μm.

When the sintered body of Ti 70 wt % and Al 30 wt % was used for the black layer 12, the black layer 12 becomes blacker than the DLC film. Moreover, the black layer 12 excels in hardness and scratch resistance than the TiC film, and the film thickness thereof can be reduced to a half of that of the TiC film. Consequently, the production cost is greatly reduced. In this manner, the black member 1 that has a high hardness and that excels in scratch resistance can be obtained by using the sintered body of Ti 70 wt % and Al 30 wt %.

TABLE 1

| | Film | Film | | | | | | | | | | Scratch | |
|---|---|---|---|---|---|---|---|---|---|---|---|---|---|
| | Formation | Thickness | Color Tone | | | Hardness | ESCA (at %) | | | | | Resistance | |
| Sample | Conditions | μm | L* | a* | b* | HV | Ti | Al | N | O | C | Rq (Å) | Evaluation |
| 1-2 | TiAl(N0_{sccm}) | 1 | 76.92 | 0.9 | 4.58 | 792.5 | 52.8 | 44.3 | 2.5 | 0.4 | | 899 | X |
| 1-3 | TiAl(N10_{sccm}) | 1 | 76.06 | 0.88 | 3.84 | 1084.9 | — | — | — | — | — | 674 | X |
| 1-4 | TiAl(N15_{sccm}) | 1 | 71.56 | 1.17 | 5.35 | 1304.46 | 35.2 | 41.3 | 21.9 | 1.4 | 0.2 | 468 | X |
| 1-5 | TiAl(N20_{sccm}) | 1 | 67.44 | 2.17 | 7.68 | 1996.66 | 30.5 | 36.6 | 30 | 2.5 | 0.4 | 357 | X |
| 1-6 | TiAl(N25_{sccm}) | 1 | 42.57 | 5.02 | 4.89 | 1367.6 | — | — | — | — | — | 423 | X |
| 1-7 | TiAl(N30_{sccm}) | 1 | 37.24 | 3.31 | 3.03 | 1090.3 | 24.6 | 32.4 | 37.4 | 5 | 0.6 | 522 | X |
| 1-1 | TiAl(N35_{sccm}) | 1 | 36.35 | 2.24 | 2.6 | 1029.98 | 22.5 | 31.7 | 40.9 | 4.1 | 0.8 | 654 | ⊚ |
| 1-8 | TiAl(N40_{sccm}) | 1 | 40.83 | 1.74 | 1.28 | 1055.15 | 20.6 | 28.5 | 45.1 | 4.9 | 0.9 | 648 | ⊚ |
| 1-9 | TiAl(N50_{sccm}) | 1 | 40.55 | 1.41 | 1.49 | 1106.27 | 18.2 | 26.8 | 48.6 | 5.4 | 1 | 660 | ⊚ |
| 1-10 | TiAl(N60_{sccm}) | 1 | 39.87 | 1.41 | 3.09 | 998 | — | — | — | — | — | 718 | X |

| | | | | | | | | | | | | |
|---|---|---|---|---|---|---|---|---|---|---|---|---|
| DLC Film | 1 | 48.89 | 0.26 | 1.66 | 1350 | 0 | 0 | 0 | 6.2 | 93.8 | 408 | X |
| TiC Film Company A | 3.3 | 35.69 | 0.52 | 1.6 | 285 | 13.5 | 0 | 0.9 | 3.1 | 82.5 | 1008 | X |
| TiC Film Company B | 3.1 | 42.23 | 0.38 | 1.7 | 416 | — | — | — | — | — | 1249 | X |
| Ideal Black Layer | 1 | 24.25 | −1.29 | 1.32 | — | — | — | — | — | — | — | — |

In the film formation conditions in Table 1, TiAl (N35_{sccm}) indicates that 35 sccm of nitrogen gas was introduced to the base 11. Similarly, TiAl (N10_{sccm}) or the like indicates that 10 sccm of nitrogen gas was introduced to the base 11. The same applies to the other tables.

### Example 2

In Example 2, the sintered body of Ti 70 wt % and Al 30 wt % (Ti 57 at % and Al 43 at %) was used as a sputtering target (raw material alloy). As illustrated in FIG. 2, a Ti material of JIS class 2 was used as the base 21. The black member 2 was produced (sample 2-1) by forming the black layer 22 (TiAl alloy oxynitride film) with a thickness of 1.0 μm on the base 21, by introducing nitrogen gas and oxygen gas under a constant Ar gas amount of 105 sccm using the sputtering method. A Bias voltage for firmly attaching the film material to be sputtered was applied to the base 21, and Example 2 was performed under a fixed condition in which the Bias voltage is −10 V. A sample in which the black layer 22 is formed on the SUS316L base defined in JIS was also produced at the same time, as a sample for the scratch resistance test.

Moreover, the black member 2 was produced by changing the nitrogen gas amount and the oxygen gas amount, by using the sintered body of Ti 70 wt % and Al 30 wt % (samples 2-2 to 2-7). Table 2 indicates the film thickness, color tone, and film hardness of the black layer 22, and the film component measurement results by ESCA and the scratch resistance test results, of these samples. As a comparison, Table 2 also indicates the film thickness, color tone, film hardness, and the like of the DLC film, TiC film (company A and company B), and the ideal black layer, with a part of measurement results in Table 1.

When a small amount of oxygen gas was added in addition to nitrogen gas, the color tone range (L*≤48.0, −2.0≤a*≤3.0, and −3.5≤b*≤3.0) that displays black with a luxurious feel is satisfied, and the film hardness of HV1000 or more can be achieved.

Moreover, Table 2 reveals that by introducing oxygen in addition to nitrogen, L*, a*, and b* are reduced and the color tone becomes closer to black, similar to when the amount of nitrogen was simply increased. However, when the oxygen amount is increased, b* is reduced and the hardness is reduced, and the black layer becomes bluish black, after a certain condition is satisfied. When the oxygen amount is increased furthermore, a thin-film interference phenomenon occurs, and black will not be displayed, as the TiC film of Example 1 illustrated in FIG. 9.

When the total amount of nitrogen gas and oxygen gas is equivalent to the amount of nitrogen gas alone (for example, 35 sccm in total), and when these conditions were compared, the film hardness was increased when oxygen was introduced to the base 21 in addition to nitrogen. This is because when oxygen is introduced to the base 21, aluminum oxide or aluminum oxide nitride that has a high hardness is formed in the film. Because titanium oxide with low hardness is also formed at the same time, it is considered that the hardness is reduced after exceeding a certain amount.

When the amounts of elements in the film using ESCA are compared, it is revealed that oxygen is more easily taken into the film than nitrogen even in a small amount. This is derived from the fact that the free energy of forming an oxide film containing titanium and aluminum is lower than that of forming a nitride film containing titanium and aluminum.

As in Example 2, by using both nitrogen gas and oxygen gas for the sintered body of Ti 70 wt % and Al 30 wt %, it is possible to provide the black member 2 that has a high hardness and that excels in scratch resistance, than using nitrogen gas alone.

TABLE 2

| | | Film | | | | | | | | | | Scratch | |
|---|---|---|---|---|---|---|---|---|---|---|---|---|---|
| | Film Formation | Thickness | Color Tone | | | Hardness | ESCA (at %) | | | | | Resistance | |
| Sample | Conditions | μm | L* | a* | b* | HV | Ti | Al | N | O | C | Rq (Å) | Evaluation |
| 1-5 | TiAl(N20_{sccm}) | 1 | 67.44 | 2.17 | 7.68 | 1996.66 | 30.5 | 36.6 | 30 | 2.5 | 0.4 | 357 | X |
| 1-7 | TiAl(N30_{sccm}) | 1 | 37.24 | 3.31 | 3.03 | 1090.3 | 24.6 | 32.4 | 37.4 | 5 | 0.6 | 522 | X |
| 1-1 | TiAl(N35_{sccm}) | 1 | 36.35 | 2.24 | 2.6 | 1029.98 | 22.5 | 31.7 | 40.9 | 4.1 | 0.8 | 654 | ⊚ |
| 1-8 | TiAl(N40_{sccm}) | 1 | 40.83 | 1.74 | 1.28 | 1055.15 | 20.6 | 28.5 | 45.1 | 4.9 | 0.9 | 648 | ⊚ |
| 2-1 | TiAl(N20O10_{sccm}) | 1 | 44.6 | 2.7 | 2.98 | 1161.9 | 20.8 | 24.1 | 26.7 | 28.4 | — | 697 | ⊚ |
| 2-2 | TiAl(N20O15_{sccm}) | 1 | 43.8 | 1.65 | −2.9 | 1396.52 | 19.3 | 23.2 | 22.6 | 34.9 | — | 501 | ⊚ |
| 2-3 | TiAl(N20O20_{sccm}) | 1 | 43.75 | 0.54 | −3.63 | 975.24 | 19 | 21.2 | 21.1 | 38.7 | — | 789 | X |
| 2-4 | TiAl(N30O5_{sccm}) | 1 | 38.04 | 1.77 | 0.84 | 1210.33 | 19.8 | 28.4 | 33.7 | 18.1 | — | 668 | ⊚ |
| 2-5 | TiAl(N30O10_{sccm}) | 1 | 45.64 | 0.57 | −2.68 | 1500.82 | 14 | 24.6 | 28.9 | 32.5 | — | 491 | ⊚ |
| 2-6 | TiAl(N30O15_{sccm}) | 1 | 45.64 | −0.74 | −3.45 | 966.82 | 13.7 | 22 | 27 | 37.3 | — | 801 | ◯ |
| 2-7 | TiAl(N30O20_{sccm}) | 1 | Inter- | Inter- | Inter- | 744.49 | — | — | — | — | — | 951 | X |
| | | | ference | ference | ference | | | | | | | | |
| | | | Color | Color | Color | | | | | | | | |

| | | | | | | | | | | | | |
|---|---|---|---|---|---|---|---|---|---|---|---|---|
| DLC Film | 1 | 48.89 | 0.26 | 1.66 | 1350 | 0 | 0 | 0 | 6.8 | 93.2 | 408 | X |
| TiC Film Company A | 3.3 | 35.69 | 0.52 | 1.6 | 285 | 13.5 | 0 | 0.9 | 3.1 | 82.5 | 1008 | X |
| TiC Film Company B | 3.1 | 42.23 | 0.38 | 1.7 | 416 | — | — | — | — | — | 1249 | X |
| Ideal Black Layer | 1 | 24.25 | −1.29 | 1.32 | — | — | — | — | — | — | — | X |

In the film formation conditions in Table 2, TiAl (N20_{sccm}O10_{sccm}) indicates that 20 sccm of nitrogen gas and 10 sccm of oxygen gas were introduced to the base 21. Similarly, TiAl (N20_{sccm}O15_{sccm}) or the like indicates that 20 sccm of nitrogen gas and 15 sccm of oxygen gas were introduced to the base 21, or the like. The same applies to the other tables.

### Example 3

In Example 3, the sintered body of Ti 70 wt % and Al 30 wt % (Ti 57 at % and Al 43 at %) was used as a sputtering target (raw material alloy). As illustrated in FIG. 3, the SUS316L base defined in JIS was used as the base 31. The black member 3 was produced (sample 3-1) by forming the black layer 32 (TiAl alloy nitride fluoride film) with a thickness of 1.0 μm on the base 31, by introducing nitrogen gas and CF₄ gas under a constant Ar gas amount of 105 sccm using the sputtering method. A Bias voltage for firmly attaching the film material to be sputtered was applied to the base 31, and Example 3 was performed under a fixed condition in which the Bias voltage is −10 V.

Moreover, the black member 3 was produced (samples 3-2 to 3-8) by using the sintered body of Ti 70 wt % and Al 30 wt %, while changing the nitrogen gas amount and CF₄ gas amount. Table 3 indicates the film thickness, color tone, and film hardness of the black layer 32, and the film component measurement results by ESCA and the scratch resistance test results, of these samples. As a comparison, Table 3 also indicates the film thickness, color tone, film hardness, and the like of the DLC film, TiC film (company A and company B), and the ideal black layer, with a part of the measurement results of Table 1.

When CF₄ gas was increased in addition to nitrogen gas, the degree of blackness is further improved, and approaches the ideal black. Table 3 indicates that the degree of blackness of the black layer 32 is significantly improved than that of the TiC film.

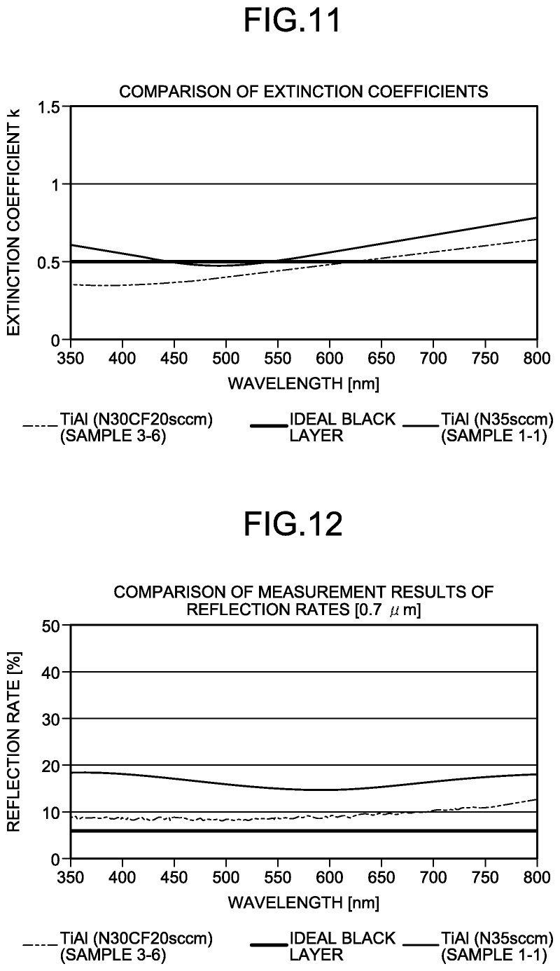

FIG. 10 to FIG. 12 are graphs each illustrating refractive indexes, extinction coefficients, and reflection rates simulated from the refractive index, extinction coefficient, and film thickness (0.7 μm) of the black layer 32 (sample 3-6), the ideal black layer, and the black layer 12 (Example 1 and sample 1-1). FIG. 10 to FIG. 12 reveal that the refractive index and the extinction coefficient of the black layer 32 approach those of the ideal black layer, when the sintered body of Ti 70 wt % and Al 30 wt % was used.

In this manner, by using both nitrogen gas and CF₄ gas for the sintered body of Ti 70 wt % and Al 30 wt %, it is possible to provide the black member 3 that displays black close to that of the ideal black layer.

TABLE 3

| | | Film | | | | | | | | | | | Scratch | |
|---|---|---|---|---|---|---|---|---|---|---|---|---|---|---|
| | Film Formation | Thickness | Color Tone | | | Hardness | ESCA (at %) | | | | | | Resistance | |
| Sample | Conditions | μm | L* | a* | b* | HV | Ti | Al | N | O | C | F | Rq (Å) | Evaluation |
| 1-5 | TiAl(N20_{sccm}) | 1 | 67.44 | 2.17 | 7.68 | 1997 | 30.5 | 36.6 | 30 | 2.5 | 0.4 | — | 357 | X |
| 1-7 | TiAl(N30_{sccm}) | 1 | 37.24 | 3.31 | 3.03 | 1090 | 24.6 | 32.4 | 37.4 | 5 | 0.6 | — | 522 | X |
| 1-1 | TiAl(N35_{sccm}) | 1 | 36.35 | 2.24 | 2.6 | 1030 | 22.5 | 31.7 | 40.9 | 4.1 | 0.8 | — | 654 | ⊚ |
| 1-8 | TiAl(N40_{sccm}) | 1 | 40.83 | 1.74 | 1.28 | 1055 | 20.6 | 28.5 | 45.1 | 4.9 | 0.9 | — | 648 | ⊚ |
| 3-1 | TiAl(N20CF10_{sccm}) | 1 | 57.06 | 1.08 | 0.06 | 1426 | — | — | — | — | — | — | 529 | X |
| 3-2 | TiAl(N20CF15_{sccm}) | 1 | 46.97 | 1.62 | 0.83 | 824 | — | — | — | — | — | — | 800 | ◯ |
| 3-3 | TiAl(N20CF20_{sccm}) | 1 | 34.78 | 0.74 | 1.58 | 504 | 19.9 | 21.4 | 20.2 | 1.8 | 7.5 | 29.2 | 1008 | ◯ |
| 3-4 | TiAl(N30CF10_{sccm}) | 1 | 46.6 | 1.18 | −2.3 | 868 | 22.5 | 30.2 | 23.8 | 2.8 | 6.5 | 14.2 | 903 | ◯ |
| 3-5 | TiAl(N30CF15_{sccm}) | 1 | 37.28 | 1.54 | 1.28 | 749 | — | — | — | — | — | — | 1266 | ◯ |
| 3-6 | TiAl(N30CF20_{sccm}) | 1 | 29.87 | 1.13 | 1.94 | 534 | 19.5 | 24.8 | 22 | 1.5 | 6.8 | 25.4 | 1214 | ◯ |
| 3-7 | TiAl(N30CF25_{sccm}) | 1 | Inter- | Inter- | Inter- | 481 | — | — | — | — | — | — | 1255 | X |
| | | | ference | ference | ference | | | | | | | | | |
| | | | Color | Color | Color | | | | | | | | | |
| 3-8 | TiAl(N30CF30_{sccm}) | 1 | Inter- | Inter- | Inter- | 512 | — | — | — | — | — | — | 1378 | X |
| | | | ference | ference | ference | | | | | | | | | |
| | | | Color | Color | Color | | | | | | | | | |

| | | | | | | | | | | | | | |
|---|---|---|---|---|---|---|---|---|---|---|---|---|---|
| DLC Film | 1 | 48.89 | 0.26 | 1.66 | 1350 | 0 | 0 | 0.8 | 6.8 | 92.4 | — | 408 | X |
| TiC Film Company A | 3.3 | 35.69 | 0.52 | 1.6 | 285 | 13.5 | 0 | 0.9 | 3.1 | 82.5 | — | 1008 | X |
| TiC Film Company B | 3.1 | 42.23 | 0.38 | 1.7 | 416 | — | — | — | — | — | — | 1249 | X |
| Ideal Black Layer | 1 | 24.25 | −1.29 | 1.32 | — | — | — | — | — | — | — | — | — |

In the film formation conditions in Table 3, TiAl (N20_{sccm}CF10_{sccm}) indicates that 20 sccm of nitrogen gas and 10 sccm of CF₄ gas were introduced to the base 31. Similarly, TiAl (N20_{sccm}CF15_{sccm}) or the like indicates that 20 sccm of nitrogen gas and 15 sccm of CF₄ gas were introduced to the base 31. The same applies to the other tables.

### Example 4

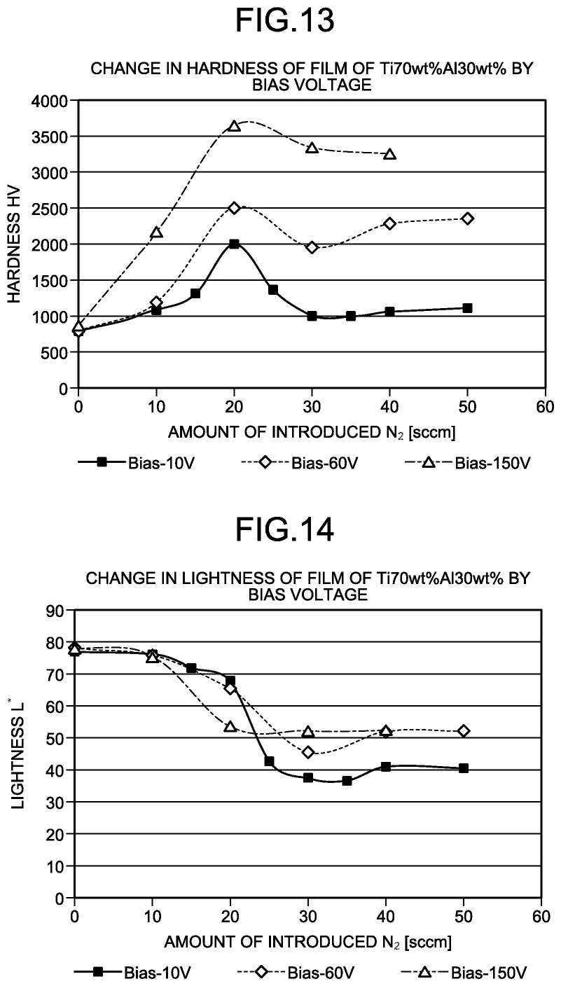

In Example 4, the sintered body of Ti 70 wt % and Al 30 wt % (Ti 57 at % and Al 43 at %) was used as a sputtering target (raw material alloy). FIG. 13 is a graph illustrating a change in hardness, by changing the nitrogen gas amount and the Bias voltage to be applied to the base. FIG. 14 is a graph illustrating a change in lightness (L*), by changing the nitrogen gas amount and the Bias voltage to be applied to the base.

As illustrated in FIG. 13, the hardness is significantly improved with an increase in the Bias voltage to be applied. It is possible to improve the film hardness of the TiAl alloy nitride film with an increase in the Bias voltage. The TiAl alloy nitride film is a material that may be used for tools. In manufacturing tools, the durability is improved with an increase in the Bias voltage. However, as illustrated in FIG. 14, when the Bias voltage is increased, the lightness becomes high (bright), and the degree of blackness is reduced.

The hardness and color tone can be changed by adjusting the Bias voltage. Consequently, when the Bias voltage and the amount of gas to be introduced are changed during the formation of a film, it is possible to produce the black layer that has a high hardness and a high degree of blackness.

### Example 5

In Example 5, the black member 4 having a suitable structure illustrated in FIG. 4 was produced. This black member 4 was made by laminating the adhesion layer 43, the adhesion gradient layer 44, the hardening layer 45, the black gradient layer 46, and the black layer 42 in this order, on the base 41. The sintered body of Ti 70 wt % and Al 30 wt % (Ti 57 at % and Al 43 at %) was used as a sputtering target (raw material alloy), and the SUS316L base defined in JIS was used as the base 41. First, the adhesion layer 43 (thickness of 0.1 μm) that is TiAl alloy film was formed on the base 41, by introducing Ar gas amount of 105 sccm using the sputtering method, and under the condition in which the Bias voltage is −150 V. Next, the adhesion gradient layer 44 (thickness of 0.15 μm) was formed on the adhesion layer 43, under the condition in which the Bias voltage is −150 V, and by introducing and increasing nitrogen gas in a gradient manner from 0 sccm to 20 sccm from the base 41 side. Next, the hardening layer 45 (thickness of 0.8 μm) was formed on the adhesion gradient layer 44, under the conditions in which the Bias voltage is −150 V and the nitrogen gas amount is 20 sccm. Next, the black gradient layer 46 (thickness of 0.15 μm) was formed on the hardening layer 45, under the condition in which the Bias voltage is −10 V, and by changing nitrogen gas from 20 sccm to 30 sccm, and CF₄ gas from 0 sccm to 20 sccm in a gradient manner from the base 41 side. Finally, the black layer 42 (thickness of 0.6 μm) was formed on the black gradient layer 46, under the conditions in which the Bias voltage is −10 V, the nitrogen gas amount is 30 sccm, and the CF₄ gas amount is 20 sccm. Consequently, the black member 40 was produced (sample 5-1).

From FIG. 14, because the lightness (L*) of the hardening layer 45 is about 70, and differs greatly from the lightness (L*) (29.87) of the black layer 42, it is considered that interference occurs when the black layer 42 is formed on the hardening layer 45. In Example 5, by providing the black gradient layer 46, the interface between the hardening layer 45 and the black layer 42 becomes obscure, and the interference phenomenon was reduced. As a result, it is possible to reduce the film thickness of the black layer 42. The black layer 42 is a layer for determining the color of the black member 4, and it is preferable to form the black layer 42 under the film formation conditions in which the layer becomes the blackest. However, compared to the hardening layer 45, the hardness of the black layer 42 is low. Thus, to secure high scratch resistance, it is preferable to reduce the film thickness.

Table 4 indicates the basic characteristics of the black member 4. As a comparison, Table 4 also indicates the characteristics of the sample 3-6 (Example 3, film formation condition: TiAl (N30CF20 sccm) (Table 3)). By introducing the hardening layer 45 that has a high hardness under the black layer 42 as in the black member 4, the film hardness of the entire black member 4 was increased, and the black member 4 that has a high hardness and that excels in scratch resistance was produced.

TABLE 4

| | | Film | | | | | Scratch |
|---|---|---|---|---|---|---|---|
| | Film Formation | Thickness | Color Tone | | | Hardness | Resistance |
| Sample | Conditions | μm | L* | a* | b* | HV | Rq (Å) |
| 5-1 | Laminated | 1.8 | 31.18 | 1.15 | 1.97 | 1261 | 502 |
| | Structure | | | | | | |
| 3-6 | TiAl(N30CF20_{sccm}) | 1 | 29.87 | 1.13 | 1.94 | 534 | 1214 |

### Example 6

In Example 6, the black member 1 and the black member 2 illustrated in FIG. 1 and FIG. 2 were produced. The sintered bodies of Ti 80 wt % and Al 20 wt % (Ti 69 at % and Al 31 at %), Ti 60 wt % and Al 40 wt % (Ti 46 at % and Al 54 at %), Ti 40 wt % and Al 60 wt % (Ti 27 at % and Al 73 at %), and Ti 30 wt % and Al 70 wt % (Ti 19 at % and Al 81 at %) were each used as a sputtering target (raw material alloy). The SUS316L base defined in JIS was used as the bases 11 and 21. The black member 1 or the black member 2 (samples 6-1 to 6-35) was produced by forming the black layer 12 or 22 (TiAl alloy nitride film or TiAl alloy oxynitride film) with a thickness of 1.0 μm on the base 11 or 21, by introducing nitrogen gas, or nitrogen gas and oxygen gas under a constant Ar gas amount of 105 sccm using the sputtering method. A Bias voltage for firmly attaching the film material to be sputtered was applied to the bases 11 and 21, and Example 6 was performed under a fixed condition in which the Bias voltage is −10 V.

Table 5 indicates the basic characteristics of the nitride film or the oxynitride film when the sintered body of Ti 80 wt % and Al 20 wt % was used. The film hardness is increased with an increase in the ratio of Ti, and the color tones L* and a* tend to increase at the same time. When oxygen gas was introduced to the bases 11 and 21 in addition to nitrogen gas, the color tone b* tends to increase.

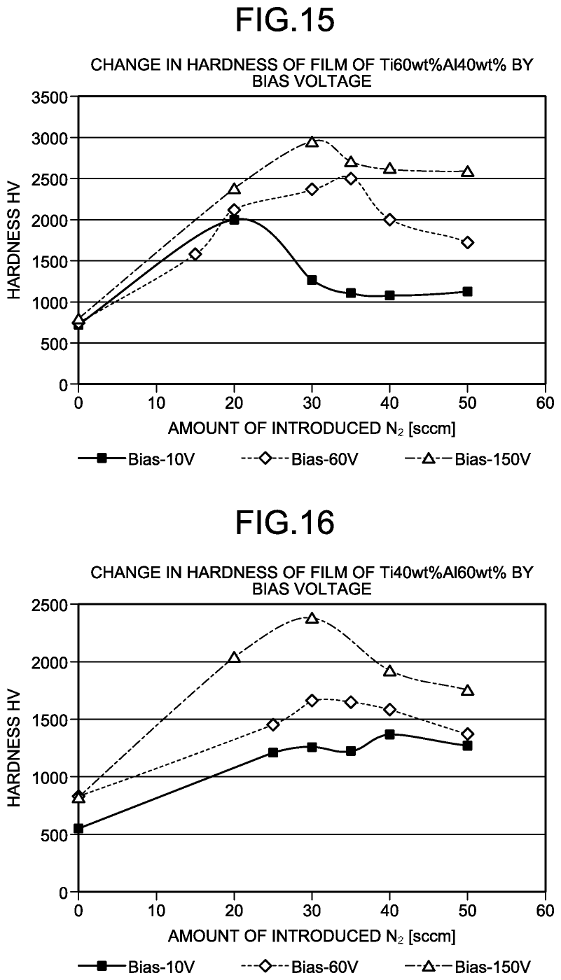

Table 6 indicates the basic characteristics of the nitride film or the oxynitride film, when the sintered body of Ti 60 wt % and Al 40 wt % was used. Because the composition of the sintered body of Ti 60 wt % and Al 40 wt % is close to that of the sintered body of Ti 70 wt % and Al 30 wt %, the basic characteristics are substantially the same. FIG. 15 is a graph illustrating a change in hardness of a nitride film by the Bias voltage, when the sintered body of Ti 60 wt % and Al 40 wt % was used. Similar to when the sintered body of Ti 70 wt % and Al 30 wt % was used, the hardness is significantly increased with an increase in the Bias. Similar to Example 5, it is possible to produce the black member with high scratch resistance by the laminated structure.

Table 7 indicates the basic characteristics of the nitride film or the oxynitride film, when the sintered body of Ti 40 wt % and Al 60 wt % was used. In this case also, it is possible to produce the black member that has a high hardness and that displays black with a luxurious feel. FIG. 16 is a graph illustrating a change in hardness of a nitride film by the Bias voltage, when the sintered body of Ti 40 wt % and Al 60 wt % was used. The hardness is significantly increased with an increase in the Bias. Similar to Example 5, it is possible to produce the black member with high scratch resistance by the laminated structure.

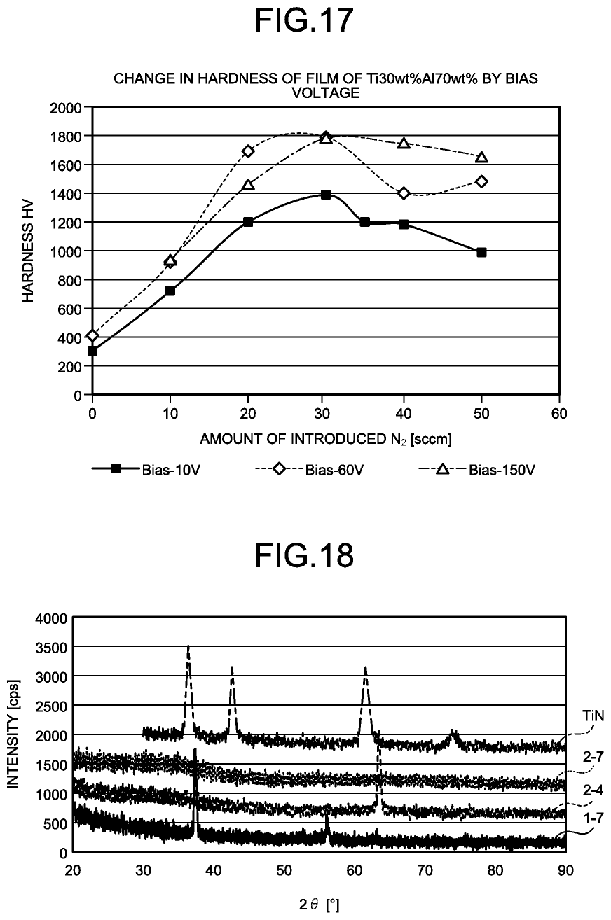

Table 8 indicates the basic characteristics of the nitride film or the oxynitride film, when the sintered body of Ti 30 wt % and Al 70 wt % was used. In this case also, it is possible to produce the black member that has a high hardness and that displays black with a luxurious feel. When the ratio of Al is increased in the nitride film, the range of conditions for displaying black tends to narrow slightly. Moreover, when the ratio of Al is increased in the oxynitride film, the lightness tends to be reduced. FIG. 17 is a graph illustrating a change in hardness of a nitride film by the Bias voltage, when the sintered body of Ti 30 wt % and Al 70 wt % was used. The hardness is increased with an increase in the Bias voltage. Similar to Example 5, it is possible to produce the black member with high scratch resistance by the laminated structure. Moreover, the hardness increase amount by the Bias voltage is reduced, with an increase in the ratio of Al in the raw material alloy.

With the nitride film that uses a sintered body of Ti 20 wt % and Al 80 wt %, the nitride films were formed into the interference film from about when the nitrogen gas amount has exceeded 30 sccm, and did not display black.

According to the above results, to produce a suitable black member, it is preferable that the ratio of the raw material alloy is from Ti 70 wt % and Al 30 wt %, to Ti 30 wt % and Al 70 wt %.

TABLE 5
Table 5

| | | | | | | | Scratch | |
|---|---|---|---|---|---|---|---|---|
| | Film Formation | Film Thickness | Color Tone | | | Hardness | Resistance | |
| Sample | Conditions | μm | L* | a* | b* | HV | Rq (Å) | Evaluation |
| 6-1 | TiAl(N20_{sccm}) | 1 | 75.13 | 1.16 | 8.89 | 1521 | 493 | X |
| 6-2 | TiAl(N30_{sccm}) | 1 | 45.28 | 8.97 | 9.28 | 1706 | 475 | X |
| 6-3 | TiAl(N40_{sccm}) | 1 | 52.64 | 6.84 | 2.96 | 2085.8 | 389 | X |
| 6-4 | TiAl(N50_{sccm}) | 1 | 53.89 | 5.33 | 1.82 | 2208.3 | 324 | X |
| 6-5 | TiAl(N30O5_{sccm}) | 1 | 48.99 | 4.27 | −2.15 | 2381.3 | 359 | X |
| 6-6 | TiAl(N30O10_{sccm}) | 1 | 45.28 | 2.19 | −3.6 | 1475.4 | 510 | X |
| 6-7 | TiAl(N25O15_{sccm}) | 1 | 45.78 | 0.79 | −4.53 | 1449.3 | 539 | X |

TABLE 6

| | | Film | | | | | Scratch | | | | | | |
|---|---|---|---|---|---|---|---|---|---|---|---|---|---|
| | Film Formation | Thickness | Color Tone | | | Hardness | Resistance | ESCA (at %) | | | | | |
| Sample | Conditions | μm | L* | a* | b* | HV | Rq (Å) | Ti | Al | N | O | C | Evaluation |
| 6-8 | TiAl(N0_{sccm}) | 1 | 77.71 | 0.72 | 4.08 | 745.17 | 921 | 44 | 54.3 | 0.8 | 0.5 | 0.4 | X |
| 6-9 | TiAl(N20_{sccm}) | 1 | 65.66 | 2.48 | 8.02 | 1993.81 | 401 | — | — | — | — | — | X |
| 6-10 | TiAl(N30_{sccm}) | 1 | 38.33 | 3.01 | 2.79 | 1258.9 | 455 | — | — | — | — | — | X |
| 6-11 | TiAl(N35_{sccm}) | 1 | 39.1 | 2.48 | 2.26 | 1098.8 | 684 | 20.3 | 41.7 | 37.3 | 0.2 | 0.5 | ⊚ |
| 6-12 | TiAl(N40_{sccm}) | 1 | 41 | 1.81 | 1.42 | 1074.56 | 705 | — | — | — | — | — | ⊚ |
| 6-13 | TiAl(N50_{sccm}) | 1 | 40.9 | 1.3 | 1.28 | 1125.3 | 608 | 15.5 | 36.6 | 46.5 | 0.6 | 0.8 | ⊚ |
| 6-14 | TiAl(N25O5_{sccm}) | 1 | 39.9 | 2.67 | 1.31 | 1212.21 | 599 | 21.3 | 30.7 | 29.9 | 17.6 | 0.5 | ⊚ |
| 6-15 | TiAl(N25O7_{sccm}) | 1 | 43.23 | 1.22 | −3.14 | 1535.91 | 507 | — | — | — | — | — | ⊚ |
| 6-16 | TiAl(N25O10_{sccm}) | 1 | 44.57 | 1.83 | −3.35 | 1676.2 | 491 | 17.5 | 23.8 | 26.7 | 31.7 | 0.3 | ⊚ |
| 6-17 | TiAl(N30O5_{sccm}) | 1 | 43.54 | 1.33 | −2.2 | 1552.51 | 555 | 18.3 | 27.7 | 29.2 | 24.4 | 0.4 | ⊚ |
| 6-18 | TiAl(N30O10_{sccm}) | 1 | 45.81 | 0.2 | −4.19 | 1566.07 | 582 | — | — | — | — | — | X |
| 6-19 | TiAl(N35O5_{sccm}) | 1 | 47.64 | 0.48 | −4.05 | 1793.85 | 479 | — | — | — | — | — | X |

TABLE 7

| | | Film | | | | | | |
|---|---|---|---|---|---|---|---|---|
| | Film Formation | Thickness | Color Tone | | | Hardness | Scratch Resistance | |
| Sample | Conditions | μm | L* | a* | b* | HV | Rq (Å) | Evaluation |
| 6-20 | TiAl(N0_{sccm}) | 1 | 79.03 | 0.92 | 3.56 | 558.32 | 1133 | X |
| 6-21 | TiAl(N25_{sccm}) | 1 | 58.19 | 1.07 | 3.11 | 1208.59 | 545 | X |
| 6-22 | TiAl(N30_{sccm}) | 1 | 52.46 | 0.9 | 2.28 | 1260.77 | 560 | X |
| 6-23 | TiAl(N35_{sccm}) | 1 | 45.58 | 0.5 | −0.74 | 1222 | 550 | ⊚ |
| 6-24 | TiAl(N40_{sccm}) | 1 | 44.9 | 0.2 | −1.57 | 1366.1 | 533 | ⊚ |
| 6-25 | TiAl(N50_{sccm}) | 1 | 46.01 | 0.33 | 0.07 | 1272.45 | 499 | ⊚ |
| 6-26 | TiAl(N30O5_{sccm}) | 1 | 33.9 | 1.55 | 2.05 | 1240 | 507 | ⊚ |

TABLE 8

| | | Film | | | | | Scratch | | | | | | |
|---|---|---|---|---|---|---|---|---|---|---|---|---|---|
| | Film Formation | Thickness | Color Tone | | | Hardness | Resistance | ESCA (at %) | | | | | |
| Sample | Conditions | μm | L* | a* | b* | HV | Rq (Å) | Ti | Al | N | O | C | Evaluation |
| 6-27 | TiAl(N0_{sccm}) | 1 | 80 | 0.95 | 3.18 | 310 | 1482 | 19.3 | 78.7 | 1.2 | 0.4 | 0.4 | X |
| 6-28 | TiAl(N10_{sccm}) | 1 | 70.33 | 1.16 | 3.23 | 723 | 1200 | — | — | — | — | — | X |
| 6-29 | TiAl(N20_{sccm}) | 1 | 62.66 | 1.17 | 3.26 | 1200 | 621 | — | — | — | — | — | X |
| 6-30 | TiAl(N30_{sccm}) | 1 | 44.06 | 0.52 | 0.68 | 1387 | 543 | 8.8 | 38.9 | 50.9 | 0.5 | 0.9 | ⊚ |
| 6-31 | TiAl(N35_{sccm}) | 1 | 40.11 | 0.53 | 0.69 | 1199 | 574 | — | — | — | — | — | ⊚ |
| 6-32 | TiAl(N40_{sccm}) | 1 | 35.75 | 0.48 | 0.67 | 1179 | 539 | — | — | — | — | — | ⊚ |
| 6-33 | TiAl(N50_{sccm}) | 1 | 41.85 | 2.18 | 4.34 | 1086 | 605 | 8.1 | 37.9 | 52.8 | 0.4 | 0.8 | X |
| 6-34 | TiAl(N30O5_{sccm}) | 1 | 30.9 | 1.6 | 2.09 | 1216 | 587 | 6.4 | 38.1 | 42.3 | 12.9 | 0.3 | ⊚ |
| 6-35 | TiAl(N30O10_{sccm}) | 1 | Inter- | Inter- | Inter- | 910 | 951 | — | — | — | — | — | X |
| | | | ference | ference | ference | | | | | | | | |
| | | | Color | Color | Color | | | | | | | | |

### Example 7

In Example 7, the black member 6 illustrated in FIG. 5 was produced. The sintered bodies from Ti 30 wt % and Si 70 wt % (Ti 20.1 at % and Si 79.9 at %) to Ti 10 wt % and Si 90 wt % (Ti 6.1 at % and Si 93.9 at %) were each used as a sputtering target (raw material alloy). The SUS316L base defined in JIS was used as the base 61. The black member 6 was produced (samples 7-1 to 7-18) by forming the black layer 62 (TiSi alloy nitride film or TiSi alloy oxynitride film) with a thickness of 1.0 μm on the base 61, by introducing nitrogen gas, or nitrogen gas and oxygen gas, under a constant Ar gas amount of 105 sccm using the sputtering method. A Bias voltage for firmly attaching the film material to be sputtered was applied to the base 61, and Example 7 was performed under a fixed condition in which the Bias voltage is −10 V.

Table 9 indicates the basic characteristics of the nitride film or the oxynitride film when a sintered body of Ti 30 wt % and Si 70 wt % was used. As a comparison, Table 9 also indicates the measurement results of TiSi. Similar to the TiAl nitride film and the TiAl oxynitride film, the TiSi nitride film and the TiSi oxynitride film have also displayed black. When the black member was produced under the condition in which the nitrogen gas amount is 30 sccm and more, the color tone range (L*≤48.0, −2.0≤a*≤3.0, and −3.5≤b*≤3.0) that displays black with a luxurious feel is satisfied, and the film hardness of HV1000 or more that is effective for scratch resistance can be achieved. The overall lightness of the TiSi nitride film and the TiSi oxynitride film is higher than that of the TiAl nitride film and the TiAl oxynitride film.

Table 10 indicates the basic characteristics of the nitride film or the oxynitride film when a sintered body of Ti 20 wt % and Si 80 wt % was used. As a comparison, Table 10 also indicates the measurement results of TiSi. In this case also, it is possible to produce the black member that has a high hardness and that displays black. When the ratio of Si in the nitride film is increased, the range of conditions for displaying black tends to become narrow.

With the nitride film that uses a sintered body of Ti 10 wt % and Si 90 wt %, the nitride films were formed into the interference film from about when the nitrogen gas amount has exceeded 30 sccm, and did not display black.

According to the above results, to produce a preferable black member, it is preferable that the ratio of the raw material alloy is from Ti 30 wt % and Si 70 wt %, to Ti 20 wt % and Si 80 wt %. Moreover, to increase the film hardness of the nitride film, it is preferable to set the ratio of Si large. Furthermore, to increase the degree of black, it is preferable to use the TiAl system than the TiSi system.

TABLE 9

| | | Film | | | | | Scratch | | | | | | |
|---|---|---|---|---|---|---|---|---|---|---|---|---|---|
| | Film Formation | Thickness | Color Tone | | | Hardness | Resistance | ESCA (at %) | | | | | |
| Sample | Conditions | μm | L* | a* | b* | HV | Rq (Å) | Ti | Si | N | O | C | Evaluation |
| 7-1 | TiSi(N0_{sccm}) | 1 | 73.46 | 0.32 | −0.85 | 691.92 | 1103 | — | — | — | — | — | X |
| 7-2 | TiSi(N10_{sccm}) | 1 | 65.98 | 0.29 | −0.19 | 829.35 | 997 | — | — | — | — | — | X |
| 7-3 | TiSi(N20_{sccm}) | 1 | 60.31 | 0.3 | 0.12 | 1010.79 | 724 | — | — | — | — | — | X |
| 7-4 | TiSi(N30_{sccm}) | 1 | 47.25 | 0.21 | −1.69 | 1331.29 | 687 | 16.2 | 40 | 40.8 | 1.8 | 1.2 | ⊚ |
| 7-5 | TiSi(N40_{sccm}) | 1 | 45.27 | 0.19 | −1.68 | 1688.49 | 622 | — | — | — | — | — | ⊚ |
| 7-6 | TiSi(N50_{sccm}) | 1 | 43.94 | 0.14 | −1.98 | 1861.84 | 589 | 8.1 | 36.8 | 52.1 | 1.5 | 1.5 | ⊚ |
| 7-7 | TlSi(N60_{sccm}) | 1 | Inter- | Inter- | Inter- | 1467.72 | 631 | — | — | — | — | — | X |
| | | | ference | ference | ference | | | | | | | | |
| | | | Color | Color | Color | | | | | | | | |
| 7-8 | TiSi(N30O5_{sccm}) | 1 | 45.97 | 0.32 | −0.39 | 1456.64 | 674 | 5.1 | 32.2 | 48.2 | 14.1 | 0.4 | ⊚ |
| 7-9 | TiSi(N30O10_{sccm}) | 1 | Inter- | Inter- | Inter- | 1266.32 | 658 | — | — | — | — | — | X |
| | | | ference | ference | ference | | | | | | | | |
| | | | Color | Color | Color | | | | | | | | |

TABLE 10

| | | Film | | | | | Scratch | | | | | | |
|---|---|---|---|---|---|---|---|---|---|---|---|---|---|
| | Film Formation | Thickness | Color Tone | | | Hardness | Resistance | ESCA (at %) | | | | | |
| Sample | Conditions | μm | L* | a* | b* | HV | Rq (Å) | Ti | Si | N | O | C | Evaluation |
| 7-10 | TiSi(N0_{sccm}) | 1 | 72.95 | 0.05 | −2.38 | 761.71 | 1116 | — | — | — | — | — | X |
| 7-11 | TiSi(N10_{sccm}) | 1 | 64.6 | 0.03 | −1.11 | 941.62 | 801 | — | — | — | — | — | X |
| 7-12 | TiSi(N20_{sccm}) | 1 | 57.31 | 0.09 | −0.75 | 1175.08 | 710 | — | — | — | — | — | X |
| 7-13 | TiSi(N30_{sccm}) | 1 | 48.86 | 0.26 | −1.02 | 1555 | 603 | — | — | — | — | — | X |
| 7-14 | TiSi(N40_{sccm}) | 1 | 45.28 | 0.2 | −1.72 | 1928.35 | 429 | 5.9 | 41.2 | 51.5 | 0.9 | 0.5 | ⊚ |
| 7-15 | TiSi(N50_{sccm}) | 1 | Inter- | Inter- | Inter- | 1992.7 | 431 | — | — | — | — | — | X |
| | | | ference | ference | ference | | | | | | | | |
| | | | Color | Color | Color | | | | | | | | |
| 7-16 | TiSi(N60_{sccm}) | 1 | Inter- | Inter- | Inter- | 2032.33 | 358 | — | — | — | — | — | X |
| | | | ference | ference | ference | | | | | | | | |
| | | | Color | Color | Color | | | | | | | | |
| 7-17 | TiSi(N30O5_{sccm}) | 1 | 46.39 | 0.38 | −0.33 | 1456.64 | 579 | 4 | 37.2 | 42.1 | 16.5 | 0.2 | ⊚ |
| 7-18 | TiSi(N30O10_{sccm}) | 1 | Inter- | Inter- | Inter- | 1266.32 | 650 | — | — | — | — | — | X |
| | | | ference | ference | ference | | | | | | | | |
| | | | Color | Color | Color | | | | | | | | |

### Example 8

In Example 8, the black member 7 illustrated in FIG. 6 was produced. A sintered body of Ti 52 Wt %, Al 28 Wt %, and Si 20 Wt % was used as a sputtering target (raw material alloy). The SUS316L base defined in JIS was used as the base 71. The black member 7 was produced (samples 8-1 to 8-10) by forming the black layer 72 (TiAlSi alloy nitride film or TiAlSi alloy oxynitride film) with a thickness of 1.0 μm on the base 71, by introducing nitrogen gas, or nitrogen gas and oxygen gas, under a constant Ar gas amount of 105 sccm using the sputtering method. A Bias voltage for firmly attaching the film material to be sputtered was applied to the base 71, and Example 8 was performed under a fixed condition in which the Bias voltage is −10 V.

Table 11 indicates the basic characteristics of the nitride film or the oxynitride film when the sintered body of Ti 52 Wt %, Al 28 Wt %, and Si 20 Wt % was used. As a comparison, Table 11 also indicates the measurement results of TiAlSi. Similar to the TiAl nitride film and the TiAl oxynitride film, the TiAlSi nitride film and the TiAlSi oxynitride film have also displayed black. When the black member was produced under the conditions in which the nitrogen gas amount is 30 sccm or more and 50 sccm or less, the nitrogen amount is 30 sccm, and the oxygen amount is 5 sccm, the color tone range (L*≤48.0, −2.0≤a*≤3.0, and −3.5≤b*≤3.0) that displays black with a luxurious feel is satisfied, and the film hardness of HV1000 or more that is effective for scratch resistance can be achieved. The overall lightness of the TiAlSi nitride film and the TiAlSi oxynitride film is higher than that of the TiAl nitride film and the TiAl oxynitride film.

Table 11 reveals that by introducing oxygen in addition to nitrogen, L*, a*, and b* are reduced and the color tone becomes closer to black, similar to when the nitrogen amount is simply increased. However, when the oxygen amount is increased more than 5 sccm, the thin-film interference phenomenon occurs, and black will not be displayed.

When the total amount of nitrogen gas and oxygen gas is equivalent to the amount of nitrogen gas alone (for example, 35 sccm in total), and when these conditions were compared, the film hardness was reduced when oxygen is introduced to the base 71. In this manner, the result is opposite to that in Example 2. This is because, when oxygen is introduced to the base 71, aluminum oxide or aluminum oxynitride that has a high hardness is formed, and silicon oxide or titanium oxide that has low hardness is formed in the film at the same time.

When the amounts of elements in the film by ESCA are compared, it is revealed that oxygen is more easily taken into the film than nitrogen even in a small amount. This is derived from the fact that free energy of forming an oxide film containing titanium, aluminum, or silicon is lower than that of forming a nitride film containing titanium, aluminum, or silicon.

As a result of Table 11, to increase the degree of black, it is preferable to use the TiAl system than the TiAlSi system.

TABLE 11

| | | Film | | | | | Scratch | | | | | | | |
|---|---|---|---|---|---|---|---|---|---|---|---|---|---|---|
| | Film Formation | Thickness | Color Tone | | | Hardness | Resistance | ESCA (at %) | | | | | | |
| Sample | Conditions | μm | L* | a* | b* | HV | Rq (Å) | Ti | Al | Si | N | O | C | Evaluation |
| 8-1 | TiAlSi(N10_{sccm}) | 1 | 69.05 | 1.08 | 3.47 | 1096.92 | 820 | — | | — | — | — | — | X |
| 8-2 | TiAlSi(N20_{sccm}) | 1 | 56.91 | 0.97 | 2.81 | 1215.2 | 709 | 22.1 | 24.1 | 12.1 | 40.8 | 0.9 | 0 | X |
| 8-3 | TiAlSi(N30_{sccm}) | 1 | 47.37 | 1.26 | 0.61 | 1360.94 | 678 | 20.5 | 21.8 | 11.8 | 45.5 | 0.4 | 0 | ⊚ |
| 8-4 | TiAlSi(N35_{sccm}) | 1 | 45.24 | 0.85 | −2.34 | 1385.59 | 681 | 18.2 | 19 | 11.3 | 51.5 | 0 | 0 | ⊚ |
| 8-5 | TiAlSi(N40_{sccm}) | 1 | 45.51 | 0.01 | −2.56 | 1369.34 | 647 | — | — | — | — | — | — | ⊚ |
| 8-6 | TiAlSi(N50_{sccm}) | 1 | 47.87 | −1.09 | −2.86 | 1245.08 | 701 | 16.8 | 19.3 | 10.9 | 52.5 | 0.5 | 0 | ⊚ |
| 8-7 | TiAlSi(N60_{sccm}) | 1 | 53.49 | 2.32 | −1.45 | 1235.45 | 731 | — | — | — | — | — | — | X |
| 8-8 | TiAlSi(N30O2_{sccm}) | 1 | 42.73 | −0.22 | −2.35 | 1102.47 | 838 | — | — | — | — | — | — | ⊚ |
| 8-9 | TiAlSi(N30O5_{sccm}) | 1 | 42.34 | −1.15 | −2.79 | 1000.49 | 843 | 15.1 | 17.3 | 12.2 | 29.1 | 26.3 | 0 | ⊚ |
| 8-10 | TiAlSi(N30O10_{sccm}) | 1 | Inter- | Inter- | Inter- | 678.6 | 1211 | — | — | — | — | — | — | X |
| | | | ference | ference | ference | | | | | | | | | |
| | | | Color | Color | Color | | | | | | | | | |

| | | | | | | | | | | | | | |
|---|---|---|---|---|---|---|---|---|---|---|---|---|---|
| TiAlSi | 1 | 77.73 | 0.94 | 2.65 | 878.6 | 896 | 40.9 | 28 | 30.1 | — | 0.9 | 0.1 | X |

### Example 9

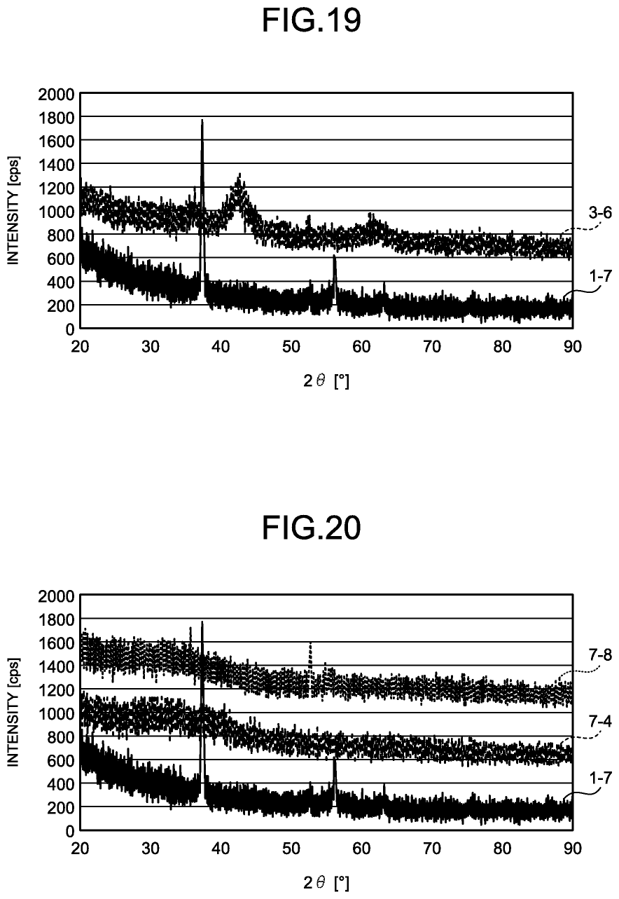

FIG. 18, FIG. 19, and FIG. 20 are each a graph illustrating measurement results of crystallinity obtained using the XRD diffraction method.

More specifically, FIG. 18 is measurement results of crystallinity of sample 1-7 (TiAl (N30 sccm)), sample 2-4 (TiAl (N3005 sccm)), and sample 2-7 (TiAl (N30020 sccm)), and TiN (Ti (N30 sccm)) used as a comparison. The diffraction peak of TiAl (N30 sccm) was around 37 degrees and 56 degrees. However, the diffraction peak of TiAl (N3005 sccm) was observed only around 63 degrees. Moreover, TiAl (N30020 sccm) does not express the preferential crystal orientation, but has an amorphous-like crystal structure. By comparing with the crystallinity of Ti (N30 sccm) that was measured as a comparison, the crystallinity of TiAlN and TiAlNO is clearly different. It is considered that the difference in crystallinity leads to the difference in color tone and hardness.

FIG. 19 is measurement results of crystallinity of sample 1-7 (TiAl (N30 sccm) and sample 3-6 (TiAl (N30CF20 sccm)). When CF₄ gas is introduced to the base, the overall diffraction peak becomes broad, and the film becomes an amorphous-like film with small crystals.

FIG. 20 is measurement results of crystallinity of sample 1-7 (TiAl (N30 sccm), sample 7-4 (TiSi (N30 sccm)), and sample 7-8 (TiSi (N3005 sccm)). TiSi (N30 sccm) and TiSi (N3005 sccm) do not have clear diffraction peaks, and have displayed nearly amorphous-like crystal structures. It has been known that the thin-film structure of Si₃N₄, which is silicon nitride, or SiO₂, which is oxide, displays a nearly amorphous structure. It is considered that the crystal structure of the TiSi film in Example 6 also has an amorphous-like crystal structure, due to high ratio of Si in the film.

### REFERENCE SIGNS LIST

1, 2, 3, 4, 6, 7 black member
11, 21, 31, 41, 61, 71 base
12, 22, 32, 42, 62, 72 black layer
43 adhesion layer
44 adhesion gradient layer
45 hardening layer
46 black gradient layer

1. A black member comprising:
a base; and
a black layer laminated on the base, wherein
the black layer contains titanium aluminum nitride, titanium silicon nitride, or titanium aluminum silicon nitride;
the black layer optionally also contains at least one type of elements selected from the group consisting of oxygen, fluorine, and carbon, and when the black layer contains carbon, and assuming that a total amount of elements contained in the black layer is 100 at %, the black layer contains carbon of 10 at % or less; and
in a color evaluation according to an L*, a*, b* color system (CIE color system), the black layer satisfies L*≤48.0, −2.0≤a*≤3.0, and −3.5≤b*≤3.0.

2. The black member according to claim 1, wherein hardness of the black member is HV1000 or more.

3. The black member according to claim 1, wherein
the black layer contains titanium aluminum nitride, and
assuming that the total amount of elements contained in the black layer is 100 at %, the black layer contains titanium of 8.8 at % or more and 22.5 at % or less, and aluminum of 26.8 at % or more and 41.7 at % or less; and when the black layer contains oxygen, the black layer contains oxygen in excess of 0 at % and 6 at % or less.

4. The black member according to claim 1, further comprising:
at least one layer selected from the group consisting of an adhesion layer, a hardening layer, and a black gradient layer; wherein
the adhesion layer, the hardening layer, and the black gradient layer are laminated in this order between the base and the black layer.

5. The black member according to claim 4, further comprising:
the adhesion layer, the hardening layer, and the black gradient layer; wherein
the adhesion layer, the hardening layer, and the black gradient layer are laminated in this order between the base and the black layer.

6. The black member according to claim 5, further comprising:
an adhesion gradient layer, wherein
the adhesion gradient layer is laminated between the adhesion layer and the hardening layer.

7. The black member according to claim 1, wherein the black layer has a thickness of 0.6 μm or more and 4.0 μm or less.

8. A method for manufacturing a black member that includes a base and a black layer laminated on the base,
the black layer contains titanium aluminum nitride, titanium silicon nitride, or titanium aluminum silicon nitride;
the black layer optionally also contains at least one type of elements selected from the group consisting of oxygen, fluorine, and carbon, and when the black layer contains carbon, and assuming that a total amount of elements contained in the black layer is 100 at %, the black layer contains carbon of 10 at % or less; and
in a color evaluation according to an L*, a*, b* color system (CIE color system), the black layer satisfies L*≤48.0, −2.0≤a*≤3.0, and −3.5≤b*≤3.0, the method for manufacturing the black member comprising:
a process of laminating the black layer on the base, by allowing alloy containing titanium and aluminum, alloy containing titanium and silicon, or alloy containing titanium, aluminum, and silicon, serving as a raw material alloy to react with nitrogen gas, nitrogen gas and oxygen gas, or nitrogen gas and fluorine-based gas serving as reactive gas, using a reactive sputtering method or an arc method; and
a process of obtaining the black member by fabricating the base laminated with the black layer.

9. The method for manufacturing the black member according to claim 8, wherein the raw material alloy contains aluminum of 43 at % or more and 81 at % or less.

10. A timepiece comprising:
an exterior component, wherein
a part or whole of the exterior component is formed of the black member according to claim 1.
